(19) United States
(12) Patent Application Publication
(10) Pub. No.: US 2014/0009187 A1
(43) Pub. Date: Jan. 9, 2014

(54) INTEGRATED CIRCUIT

(71) Applicant: Fujitsu Limited, Kawasaki-shi (JP)

(72) Inventors: Masao IDE, Kawasaki (JP); Tomohiro TANAKA, Sagamihara (JP)

(73) Assignee: Fujitsu Limited, Kawasaki-shi (JP)

(21) Appl. No.: 14/020,071

(22) Filed: Sep. 6, 2013

Related U.S. Application Data
(63) Continuation of application No. PCT/JP2011/055247, filed on Mar. 7, 2011.

(51) Int. Cl. H03K 3/012

(52) U.S. Cl. CPC H03K 3/012
USPC 327/99

(57) ABSTRACT

An integrated circuit includes an outputting unit in which a CMOS inverter configured from a first MOS transistor and a second MOS transistor for outputting a second signal using a first signal as an input thereto and a third MOS transistor that includes a gate terminal to which a control signal for controlling the outputting of the second signal is inputted and that is in an off state when the control signal indicates inhibition of the outputting of the second signal are cascade-connected to each other, and a fixing unit that fixes a value of the first signal based on the control signal. When the control signal indicates inhibition of the outputting of the second signal, the fixing unit fixes the value of the first signal to a value with which the first or second MOS transistor is placed in an off state.

### CROSS-REFERENCE TO RELATED APPLICATIONS

This application is a continuation application of International Application No. PCT/JP2011/055247, filed on Mar. 7, 2011, the entire contents of which are incorporated herein by reference.

### FIELD

The embodiments discussed herein are directed to an integrated circuit.

### BACKGROUND

A three-state inverter circuit (clocked inverter circuit) whose output assumes one of a high-level state, a low-level state and a high-impedance state is known.

FIG. 8 is a view depicting a conventional three-state inverter circuit. The three-state inverter circuit 100 is configured from totaling four transistors including NMOS transistors 101 and 102 and PMOS transistors 103 and 104. The gates of the NMOS transistor 102 and the PMOS transistor 103 are formed as a common gate, and an input signal is inputted to the gate. A control signal is inputted to the gate of the NMOS transistor 101, and the control signal inverted by an inverter 105 is inputted to the PMOS transistor 104.

When the control signal has the low level, since the NMOS transistor 101 and the PMOS transistor 104 are placed in an off state, the output of the three-state inverter circuit 100 is placed in a high impedance state. On the other hand, when the control signal has the high level, since the NMOS transistor 101 and the PMOS transistor 104 are placed in an on state, a value obtained by inverting the value of the input signal is outputted from the three-state inverter circuit 100.
[Patent Document 1] Japanese Laid-Open Patent Publication No. 2004-110490

FIG. 9 is a view depicting a dynamic selector circuit in which the three-state inverter circuit 100 described above is used.

The dynamic selector circuit 200 depicted in FIG. 9 is an m×n:1 dynamic selector circuit and includes dynamic blocks 40-1 to 40-(m/2). The three-state inverter circuit 100 is provided in each of the dynamic blocks 40-1 to 40-(m/2).

It is to be noted that the dynamic blocks 40-3 to 40-(m−2)/2 individually have a configuration similar to that of the dynamic block 40-1, and therefore, for the convenience of illustration, illustration of the dynamic blocks 40-3 to 40-(m−2)/2 is omitted in FIG. 9.

Further, the dynamic blocks 40-2 and 40-(m/2) individually have a configuration similar to that of the dynamic block 40-1, and therefore, for the convenience of illustration, a detailed configuration of the dynamic blocks 40-2 and 40-(m/2) is omitted in FIG. 9.

In the dynamic selector circuit 200, within a period (precharge period) within which a signal φ has the low level, a PMOS transistor P is placed in an on state while an NMOS transistor F is placed in an off state, and the voltage of signal lines Dyn 1 and 2 is placed in the high level. Thereafter, within a period (evaluation period) within which the signal φ has the high level, the PMOS transistor P is placed in an off state while the NMOS transistor F is placed in an on state. Within the evaluation period, the dynamic selector circuit 200 outputs one of Data signals 11 to mn (denoted as Data 11 to Data mn in FIG. 9) in response to a selection signal.

Here, for example, the selection signal is one or some of select signals 11 to mn (denoted as select 11 to select mn in FIG. 9), a sel signal (denoted as sel in FIG. 9) and block select signals 1 to (m/2) (denoted as block select 1 to block select (m/2) in FIG. 9). Further, each of the block select signals 1 to (m/2), select signals 11 to 2n, select signals 31 to 4n and select signals (m−1)1 to mn is a 1hot signal having a condition of 1hot. Here, 1hot signifies a state in which only one of the plurality of signals has the high level while the remaining signals have the low level.

Here, the block select signals 1 to (m/2) are signals provided corresponding to the dynamic blocks 40-1 to 40-(m/2). The block select signals 1 to (m/2) are signals indicating whether or not signals outputted from the dynamic blocks 40-1 to 40-(m/2) are to be outputted from the corresponding three-state inverter circuits 100. For example, when the block select signal has the low level, each of the signals indicates that outputting of the three-state inverter circuit 100 is to be inhibited.

A time chart relating to the dynamic selector circuit 200 depicted in FIG. 9 is depicted in FIG. 10. In the time chart depicted in FIG. 10, also when the block select signals 1 and 2 corresponding to the dynamic blocks 40-1 and 40-2 have the low level, the output signals of the dynamic blocks 40-1 and 40-2 are individually placed in the low level or the high level. In particular, also when the block select signals 1 to (m/2) corresponding to the dynamic blocks 40-1 to 40-(m/2) have the low level, the outputs of the dynamic blocks 40-1 to 40-(m/2) are placed in the low level or the high level and are not fixed to one of the values.

Accordingly, in order to avoid collision of the output signals of the dynamic blocks 40-1 to 40-(m/2) with each other, the three-state inverter circuit 100 is provided at the following stage of each of the dynamic blocks 40-1 to 40-(m/2).

FIG. 11 depicts a static selector circuit in which the three-state inverter circuit 100 described above is used.

The static selector circuit 300 depicted in FIG. 11 is an m×n:1 static selector circuit and includes selectors 50-1 to 50-m. A Select signal <1:n> (denoted as select <1> to select <n> in FIG. 11) and block select signals 1 to m (denoted as block select 1 to block select m in FIG. 11) are 1hot signals.

It is to be noted that, since the selectors 50-3 to 50-(m−1) individually have a configuration similar to that of the selector 50-1, for the convenience of illustration, illustration of the selectors 50-3 to 50-(m−1) is omitted in FIG. 11.

Further, since the selectors 50-2 and 50-m individually have a configuration similar to that of the selector 50-1, for the convenience of illustration, a detailed configuration of the selectors 50-2 and 50-m is omitted in FIG. 11.

In the static selector circuit 300, Data signals outputted from the selectors 50-1 to 50-m are selected based on the select signal <1:n>. The three-state inverters 100 are controlled finally based on the block select signals 1 to m so that the output of one of the selectors 50-1 to 50-m is outputted from the three-state inverters 100.

Also in the static selector circuit 300, when the block select signals 1 to m have the low level, the outputs of the corresponding selectors 50-1 to 50-m are placed in the low level or the high level and are not fixed to one of the values.

Accordingly, in order to avoid collision of signals with each other, the three-state inverter circuits 100 are provided at the following stage of the selectors 50.

From the foregoing, increase of the speed of operation of the three-state inverter circuit is requested in order to increase the speed of operation of the entire circuitry such as a selector circuit. Further, since the conventional three-state inverter circuit includes many transistors, power consumption is high.

### SUMMARY

The present integrated circuit includes an outputting unit in which a CMOS inverter configured from a first MOS transistor and a second MOS transistor for outputting a second signal using a first signal as an input thereto and a third MOS transistor that includes a gate terminal to which a control signal for controlling the outputting of the second signal is inputted and that is in an off state when the control signal indicates inhibition of the outputting of the second signal are cascade-connected to each other between a first power supply and a second power supply that supplies a lower voltage than that of the first power supply; and a fixing unit that fixes a value of the first signal based on the control signal; wherein, when the control signal indicates inhibition of the outputting of the second signal, the fixing unit fixes the value of the first signal to a value with which the first or second MOS transistor connected to the first or second power supply without the intervention of the third MOS transistor is fixed to an off state.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1A is a view depicting a configuration of a dynamic selector circuit as an example of an embodiment;

FIG. 1B is a view depicting a configuration of a dynamic block of the dynamic selector circuit as an example of the embodiment;

FIG. 2 is a view depicting a time chart of the dynamic selector circuit as an example of the embodiment;

FIG. 3A is a view depicting another configuration of the dynamic selector circuit as an example of the embodiment;

FIG. 3B is a view depicting a configuration of a dynamic block of the dynamic selector circuit as an example of the embodiment;

FIG. 4 is a view depicting a configuration of a static selector circuit as an example of the embodiment;

FIG. 5 is a view depicting another configuration of the static selector circuit as an example of the embodiment;

FIGS. 6A, 6B and 7A, 7B are views illustrating operation of a three-state inverter as an example of the embodiment;

FIG. 8 is a view depicting a configuration of a conventional three-state inverter;

FIG. 9 is a view depicting a configuration of a dynamic selector circuit in which the conventional three-state inverter is used;

FIG. 10 is a view depicting a time chart of the dynamic selector circuit in which the conventional three-state inverter is used; and

FIG. 11 is a view depicting a configuration of a static selector circuit in which the conventional three-state inverter is used.

### DESCRIPTION OF EMBODIMENTS

In the following, an example of an embodiment according to a present integrated circuit is described with reference to the drawings.

### [A] First Embodiment

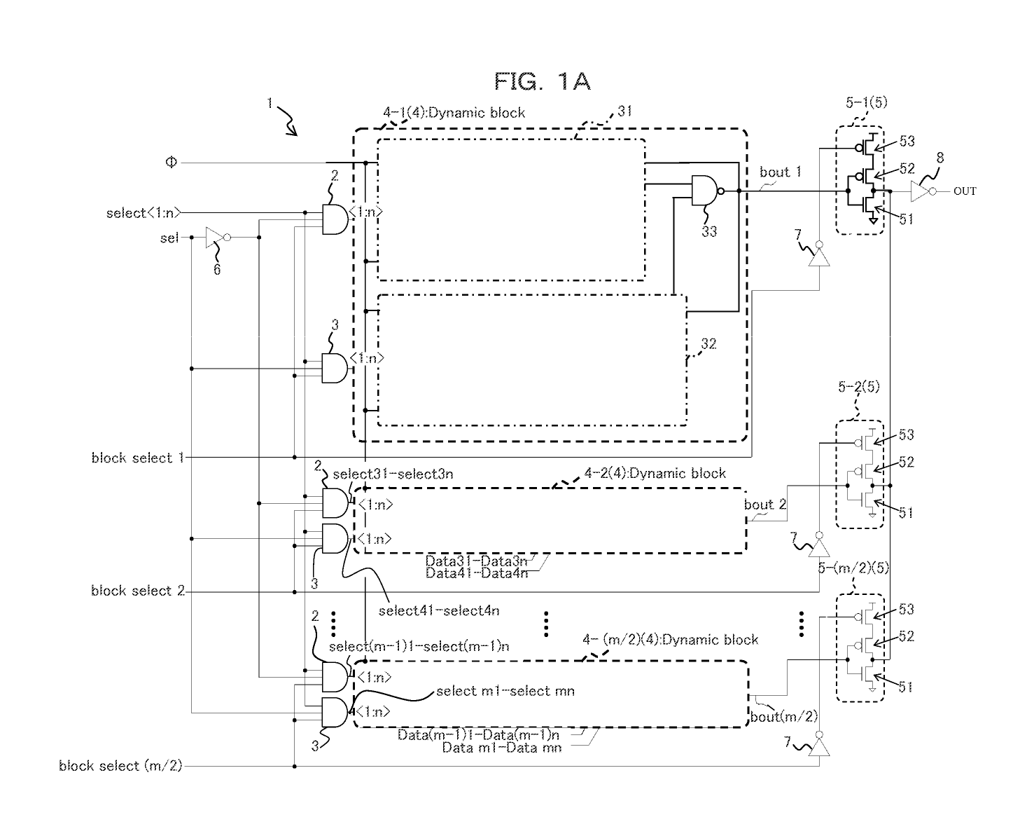

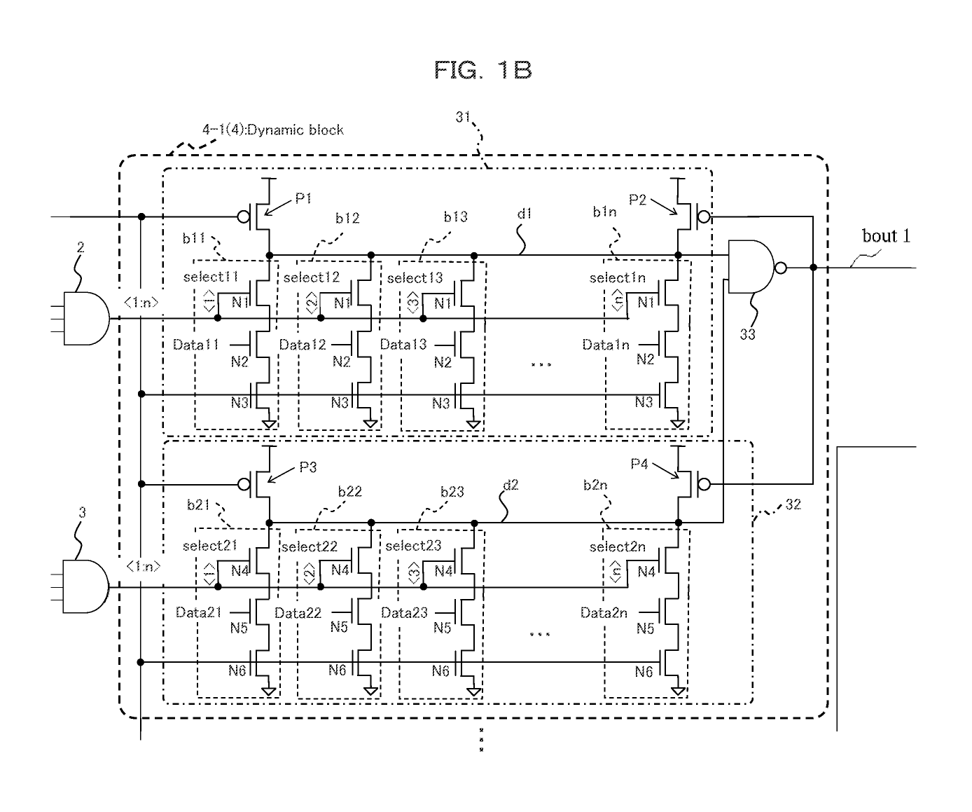

FIG. 1A is a view depicting a configuration of a dynamic selector circuit (integrated circuit) as an example of the embodiment. FIG. 1B is a view depicting a configuration of dynamic block of the dynamic selector circuit as the example of the embodiment. The dynamic selector circuit 1 depicted in FIG. 1A is an m×n:1 dynamic selector circuit. It is to be noted that “n” indicates the number of NMOS transistors N1 in a block 31 hereinafter described or the number of NMOS transistors N4 in a block 32 hereinafter described and “m” indicates the total number of blocks 31 and 32 included in the dynamic selector circuit 1.

As depicted in FIGS. 1A and 1B, the dynamic selector circuit 1 according to the first embodiment includes an AND circuit 2, another AND circuit 3, dynamic blocks 4-1 to 4-(m/2), three-state inverters 5-1 to 5-(m/2), a NOT circuit 6, another NOT circuit 7 and a further NOT circuit 8.

The three-state inverters 5-1 to 5-(m/2) are provided corresponding to the dynamic blocks 4-1 to 4-(m/2), respectively. The NOT circuit 7 is provided in each of the dynamic blocks 4-1 to 4-(m/2). The AND circuits 2 and 3 are provided in each of the dynamic blocks 4-1 to 4-(m/2).

In the following description, as a reference character for indicating a dynamic block, one of the reference characters 4-1 to 4-(m/2) is used when it is intended to specify one of the plurality of dynamic blocks. However, reference numeral 4 is used when an arbitrary dynamic block is designated.

Further, as a reference character for indicating a three-state inverter, one of reference characters 5-1 to 5-(m/2) is used when it is intended to specify one of the plurality of three-state inverters. However, reference numeral 5 is used when an arbitrary three-state inverter is designated.

It is to be noted that, since the dynamic blocks 4-3 to 4-(m−2)/2 individually have a configuration similar to that of the dynamic block 4-1, for the convenience of illustration, illustration of the dynamic blocks 4-3 to 4-(m−2)/2 is omitted.

Further, since the three-state inverters 5-3 to 5-(m−2)/2 individually have a configuration similar to that of the three-state inverter 5-1, for the convenience of illustration, illustration of the three-state inverters 5-3 to 5-(m−2)/2 is omitted in FIG. 1A.

Further, in FIG. 1A, illustration of the NOT circuits 7 connected individually to the three-state inverters 5-3 to 5-(m−2)/2 and the NAND circuits 2 and 3 connected individually to the dynamic blocks 4-3 to 4-(m−2)/2 is omitted.

Further, since the dynamic blocks 4-2 and 4-(m/2) individually have a configuration similar to that of the dynamic block 4-1, for the convenience of illustration, a detailed configuration of the dynamic blocks 4-2 and 4-(m/2) is omitted.

A connection relationship among the components is described below.

To the dynamic selector circuit 1, Data signals 11 to mn, a signal φ, a sel signal, a select signal <1:n> and block select signals 1 to (m/2) (denoted as Data 11 to Data mn, φ, sel, select <1:n> and block select 1 to block select (m/2) in FIG. 1, respectively) are inputted.

In the following description, as a reference character for indicating a Data signal, one of reference characters 11 to mn is used when it is intended to specify one of the plurality of Data signals. However, the Data signals are each referred to simply as Data signal when an arbitrary Data signal is designated.

Further, as a reference character for indicating a block select signal, one of reference characters 1 to (m/2) is used when it is intended to specify one of the plurality of block select signals. However, the block select signals are each referred to simply as block select signal when an arbitrary block select signal is designated.

Further, the select signal <1:n> is hereinafter referred to sometimes and simply as select signal.

It is to be noted that the sel signal indicates which one of the Data signals inputted to the blocks 31 and 32 (hereinafter described) is to be outputted from the dynamic selector circuit 1. For example, when the sel signal has the high level, it indicates that one of the Data signals inputted to the block 32 is to be outputted from the dynamic selector circuit 1. On the other hand, when the sel signal has the low level, it indicates that one of the Data signals inputted to the block 31 is to be outputted from the dynamic selector circuit 1. In other words, the sel signal functions as a first selection signal for selecting a data signal to be outputted from among the plurality of inputted data signals.

Further, the select signal indicates on which one of the inputted Data signals a signal to be outputted to a NAND circuit 33 hereinafter described is to be based. In other words, the select signal functions as a second selection signal for selecting a data signal to be used from among the plurality of inputted data signals. It is to be noted that the select signal is, for example, a 1hot signal.

Further, the block select signal is provided corresponding to each of the dynamic blocks 4 and indicates whether or not a signal outputted from the dynamic block 4 is to be outputted from the three-state inverter 5 connected to the dynamic block 4. The block select signals 1 to (m/2) correspond to the dynamic blocks 4-1 to 4-(m/2), respectively. Further, the block select signals 1 to (m/2) correspond to the three-state inverters 5-1 to 5-(m/2), respectively. It is to be noted that the block select signal is, for example, a 1hot signal. For example, when the block select signal has the high level, it indicates that, using the signal outputted from the dynamic block 4 as an input, the corresponding three-state inverter 5 outputs a signal having the low level or the high level. On the other hand, for example, when the block select signal has the low level, the block select signal indicates that, using the signal outputted from the dynamic block 4 as an input, the corresponding three-state inverter 5 is inhibited from outputting a signal having the low level or the high level.

The signal φ is a signal in which changeover between the high level and the low level is repeated within a fixed period.

The sel signal is inputted to the NOT circuit 6, and the output of the NOT circuit 6 is connected to an input of the AND circuits 2.

The output of the NOT circuit 6 is connected to an input of the AND circuits 2 and the output of each AND circuit 2 is connected to the corresponding dynamic block 4. Further, the select signal and the block select signal corresponding to the dynamic blocks 4 to which the AND circuits 2 are connected are inputted to the AND circuits 2.

The outputs of the AND circuits 3 are connected to the dynamic blocks 4. The sel signal, select signal and the block select signal corresponding to the dynamic blocks 4 to which the AND circuits 3 are connected are inputted to inputs of the AND circuits 3.

To the dynamic blocks 4, the outputs of the AND circuits 2 and 3 are connected and the signal φ for the changeover control between a pre-charge period and an evaluation period is inputted. Further, the plurality of Data signals are inputted to the dynamic blocks 4. Further, the output of each dynamic block 4 is connected to the corresponding three-state inverter 5.

Each dynamic block 4 includes the blocks 31 and 32 and the NAND circuit 33.

To the block 31, the output of the AND circuit 2 is connected and the signal φ and the plurality of Data signals are inputted. Further, the output of the block 31 is connected to the NAND circuit 33.

The block 31 includes PMOS transistors P1 and P2 and sub blocks b11 to b1n.

As a reference character for indicating a sub block, one of reference characters b11 to b1n is used when it is intended to specify one of the plurality of sub blocks. However, reference character b1 is used when an arbitrary sub block is designated from among the sub blocks b11 to b1n.

The source of the PMOS transistor P1 is connected to a power supply. Further, the drain of the PMOS transistor P1 is connected to the drain of the PMOS transistor P2 and the sub blocks b11 to b1n through a signal line d1. More particularly, the drain of the PMOS transistor P1 is connected to the drain of the PMOS transistor P2 and the drain of an NMOS transistor N1 hereinafter described provided in each of the sub blocks b11 to b1n. Further, the drain of the PMOS transistor P1 is connected to the NAND circuit 33 through the signal line d1. Further, the signal φ is inputted to the gate of the PMOS transistor P1.

The source of the PMOS transistor P2 is connected to the power supply. Further, the drain of the PMOS transistor P2 is connected to the drain of the PMOS transistor P1 and the sub blocks b11 to b1n through the signal line d1. More particularly, the drain of the PMOS transistor P2 is connected to the drain of the PMOS transistor P1 and the drain of the NMOS transistor N1 hereinafter described provided in each of the sub blocks b11 to b1n. Further, the drain of the PMOS transistor P1 is connected to the NAND circuit 33 through the signal line d1. Further, the gate of the PMOS transistor P2 is connected to the output of the NAND circuit 33.

The sub block b1 is connected to the drain of the PMOS transistors P1 and P2 and the NAND circuit 33 through the signal line d1. Further, the output of the AND circuit 2 is connected to the sub block b1. It is to be noted that the sub block b1 is connected to the ground. In particular, the sub blocks b11 to b1n are connected in parallel to each other. Further, the output of the AND circuit 2 is connected to the sub block b1. Further, the signal φ and the plurality of Data signals are inputted to the sub blocks b1.

Each sub block b1 includes NMOS transistors N1 to N3.

The drain of the NMOS transistor N1 is connected to the drain of the PMOS transistors P1 and P2 and an input of the NAND circuit 33 through the signal line d1. Further, the source of the NMOS transistor N1 is connected to the drain of the NMOS transistor N2. The gate of the NMOS transistor N1 provided in each of the sub blocks b11 to b1n is connected to the output of the AND circuit 2. Further, AND values among the select signals <1> to <n>, an inverted sel signal and a block select signal are inputted to the gate of the NMOS transistors N1 provided in the sub blocks b11 to b1n, respectively. For example, an AND value among the select signal <1>, inverted sel signal and block select signal is inputted to the gate of the NMOS transistor N1 provided in the sub block b11.

The drain and the source of the NMOS transistor N2 are connected to the source of the NMOS transistor N1 and the drain of the NMOS transistor N3, respectively. The Data signal is inputted to the gate of the NMOS transistor N2 provided in each of the sub blocks b11 to b1n.

The drain and the source of the NMOS transistor N3 are connected to the source of the NMOS transistor N2 and the ground, respectively. The signal φ is inputted commonly to the gate of the NMOS transistors N3 provided in the sub blocks b11 to b1n.

The drains of the PMOS transistors P1 and P2, the drains of the NMOS transistors N1 provided in the sub blocks b11 to b1n and an input of the NAND circuit 33 are connected to the signal line d1.

To the block 32, the output of the AND circuit 3 is connected and the signal φ and the plurality of Data signals are inputted. Further, the output of the block 32 is connected to the NAND circuit 33.

The block 32 includes PMOS transistors P3 and P4 and sub blocks b21 to b2n.

As a reference character for indicating a sub block, one of reference characters b21 to b2n is used when it is intended to specify one of the plurality of sub blocks in the following description. However, reference character b2 is used when an arbitrary sub block from among the sub blocks b21 to b2n is designated.

The source of the PMOS transistor P3 is connected to the power supply. Further, the drain of the PMOS transistor P3 is connected to the drain of the PMOS transistor P4 and the sub blocks b21 to b2n through a signal line d2. More particularly, the drain of the PMOS transistor P3 is connected to the drain of the PMOS transistor P4 and the drain of an NMOS transistor N4 hereinafter described provided in each of the sub blocks b21 to b2n. Further, the drain of the PMOS transistor P3 is connected to the NAND circuit 33 through the signal line d2. Further, the signal φ is inputted to the gate of the PMOS transistor P3.

The source of the PMOS transistor P4 is connected to the power supply. Further, the drain of the PMOS transistor P4 is connected to the drain of the PMOS transistor P3 and the sub blocks b21 to b2n through the signal line d2. More particularly, the drain of the PMOS transistor P4 is connected to the drain of the PMOS transistor P3 and the drain of the NMOS transistor N4 provided in each of the sub blocks b21 to b2n. Further, the drain of the PMOS transistor P4 is connected to the NAND circuit 33 through the signal line d2. Further, the gate of the PMOS transistor P4 is connected to the output of the NAND circuit 33.

The sub blocks b2 are connected to the drains of the PMOS transistors P3 and P4 and the NAND circuit 33 through the signal line d2. Further, the output of the AND circuit 3 is connected to the sub blocks b2. It is to be noted that the sub blocks b2 are connected to the ground. In other words, the sub blocks b21 to b2n are connected in parallel to each other. Further, the signal φ and the plurality of Data signals are inputted to the sub blocks b2.

Each sub block b2 includes NMOS transistors N4 to N6.

The drain of the NMOS transistor N4 is connected to an input of the NAND circuit 33 and the drain of the PMOS transistors P3 and P4 through the signal line d2. Further, the source of the NMOS transistor N4 is connected to the drain of the NMOS transistor N5. The gate of the NMOS transistor N4 provided in each of the sub blocks b21 to b2n is connected to the output of the AND circuit 3. Further, AND values among the select signals <1> to <n>, the sel signal and the block select signal are inputted to the gates of the NMOS transistors N4 provided in the sub blocks b21 to b2n, respectively. For example, an AND value among the select signal <1>, the sel signal and the block select signal is inputted to the gate of the NMOS transistor N1 provided in the sub block b21.

The drain and the source of the NMOS transistor N5 are connected to the source of the NMOS transistor N4 and the drain of the NMOS transistor N6, respectively. The Data signals are inputted to the gate of the NMOS transistors N5 provided in the sub blocks b21 to b2n.

The drain and the source of the NMOS transistor N6 are connected to the source of the NMOS transistor N5 and the ground, respectively. The signal φ is inputted commonly to the gate of the NMOS transistors N6 provided in the sub blocks b21 to b2n.

The drains of the PMOS transistors P3 and P4, drains of the NMOS transistors N4 provided in the sub blocks b21 to b2n and input of the NAND circuit 33 are connected to the signal line d2.

The drains of the PMOS transistors P1 and P2 and the drain of the NMOS transistor N1 are connected to an input of the NAND circuit 33 through the signal line d1. Further, the drains of the PMOS transistors P3 and P4 and the drain of the NMOS transistor N4 are connected to another input of the NAND circuit 33 through the signal line d2. Further, the output of the NAND circuit 33 is connected to the three-state inverter 5.

It is to be noted that the configuration of the dynamic block 4 is not limited to the configuration described above.

The output of the NAND circuit 33 and the output of the NOT circuit 7 are connected to the corresponding three-state inverter 5. Further, the input of the NOT circuit 8 is connected to the output of the three-state inverter 5.

The three-state inverter 5 includes an NMOS transistor 51, a PMOS transistor 52 and another PMOS transistor 53.

The drain of the NMOS transistor 51 is connected to the PMOS transistor 52. Further, the source of the NMOS transistor 51 is grounded. In other words, the source of the NMOS transistor 51 is connected to a power supply of 0 V. Further, the gate of the NMOS transistor 51 is connected to the gate of the PMOS transistor 52. Further, the gate of the NMOS transistor 51 is connected to the output of the NAND circuit 33.

The drain and the source of the PMOS transistor 52 are connected to the drain of the NMOS transistor 51 and the drain of the PMOS transistor 53, respectively. Further, the gate of the PMOS transistor 52 is connected to the gate of the NMOS transistor 51. Further, the gate of the PMOS transistor 52 is connected to the output of the NAND circuit 33.

Here, the drain of the NMOS transistor 51 and the drain of the PMOS transistor 52 are used as the output of the three-state inverter 5. Further, the gates of the NMOS transistor 51 and the PMOS transistor 52 are used as an input of the three-state inverter 5.

The drain and the source of the PMOS transistor 53 are connected to the source of the PMOS transistor 52 and the power supply, respectively. Further, the gate of the PMOS transistor 53 is connected to the output of the NOT circuit 7.

In particular, the NMOS transistor 51 (an example of a second MOS transistor) and the PMOS transistor 52 (an example of a first MOS transistor) configure a CMOS inverter. The CMOS inverter is cascade-connected to the PMOS transistor 53 (an example of a third MOS transistor) between the power supply (first power supply) and the ground (second power supply). In other words, the three-state inverter 5 is an example of an outputting unit configured by cascade-connecting the CMOS inverter and the third MOS transistor to each other between the first power supply and the second power supply that supplies a lower voltage than that of the first power supply.

To the input of the NOT circuit 7, the corresponding block select signal is inputted. Further, the output of the NOT circuit 7 is connected to the gate of the PMOS transistor 53.

The drain of the NMOS transistor 51 and the source of the PMOS transistor 52 are connected to the input of the NOT circuit 8.

Now, functions of the components are described.

The AND circuit 2 is a circuit for outputting an AND value of signals inputted thereto. For example, the AND circuit 2 outputs an AND value among the select signal, the sel signal inverted by the NOT circuit 6 and the block select signal.

The AND circuit 3 is a circuit for outputting an AND value of inputted signals. For example, the AND circuit 3 outputs an AND value among the select signal, sel signal and block select signal.

The NOT circuit 6 is a circuit for outputting an inverted value of an inputted signal. For example, the NOT circuit 6 outputs an inverted value of an inputted sel signal.

The dynamic block 4 selectively outputs one of a plurality of Data signals inputted thereto. For example, the dynamic block 4 outputs one of the plurality of Data signals inputted thereto in response to the signal φ, select signal, sel signal and block select signal. In particular, the dynamic block 4 outputs one of the plurality of Data signals to the corresponding three-state inverter 5 in response to the signal φ and the outputs of the AND circuits 2 and 3. In other words, the dynamic block 4 is an example of a selection unit that outputs one of a plurality of inputted Data signals.

The block 31 output a signal corresponding to a signal inputted thereto. For example, the block 31 outputs a signal corresponding to one of a plurality of Data signals inputted thereto to the NAND circuit 33 in response to the signal φ and the output of the AND circuit 2 inputted thereto.

The PMOS transistor P1 performs conduction or interruption between the power supply and the signal line d1 in response to the signal φ inputted to the gate thereof.

The PMOS transistor P2 performs conduction or interruption between the power supply and the signal line d1 in response to the output of the NAND circuit 33 inputted to the gate thereof.

The sub block b1 varies the voltage of the signal line d1 in response to the signal φ, output of the AND circuit 2 and Data signal. In particular, the sub block b1 varies the voltage of the signal line d1 in response to the signal φ, block select signal, select signal, sel signal and Data signal.

The NMOS transistor N1 performs conduction or interruption between the signal line d1 and the NMOS transistor N2 in response to the output of the AND circuit 2 inputted to the gate thereof.

Accordingly, when the block select signal has the low level, since the output of the AND circuit 2 is placed in the low level and the NMOS transistor N1 is placed in an off state, the signal line d1 is fixed to a voltage (high level) after the pre-charge.

The NMOS transistor N2 performs conduction or interruption between the NMOS transistor N1 and the NMOS transistor N3 in response to the Data signal inputted to the gate thereof.

The NMOS transistor N3 performs conduction or interruption between the NMOS transistor N2 and the ground in response to the signal φ inputted to the gate thereof.

The block 32 outputs a signal in response to a signal inputted thereto. For example, the block 32 outputs a signal corresponding to one of a plurality of Data signals inputted thereto to the NAND circuit 33 in response to the signal φ and the output of the AND circuit 3 inputted thereto.

The PMOS transistor P3 performs conduction or interruption between the power supply and the signal line d2 in response to the signal φ inputted to the gate thereof.

The PMOS transistor P4 performs conduction or interruption between the power supply and the signal line d2 in response to the output of the NAND circuit 33 inputted to the gate thereof.

The sub block b2 varies the voltage of the signal line d2 in response to the signal φ, output of the AND circuit 3 and Data signal. In particular, the sub block b2 varies the voltage of the signal line d2 in response to the signal φ, block select signal, select signal, sel signal and Data signal.

The NMOS transistor N4 performs conduction or interruption between the signal line d2 and the NMOS transistor N5 in response to the output of the AND circuit 3 inputted to the gate thereof.

Accordingly, when the block select signal has the low level, since the output of the AND circuit 3 is placed in the low level and the NMOS transistor N4 is placed in an off state, the signal line d2 is fixed to a voltage (high level) after the pre-charge.

The NMOS transistor N5 performs conduction or interruption between the NMOS transistor N4 and the NMOS transistor N6 in response to the Data signal inputted to the gate thereof.

The NMOS transistor N6 performs conduction or interruption between the NMOS transistor N5 and the ground in response to the signal φ inputted to the gate thereof.

The NAND circuit 33 is a circuit for outputting a NAND value of inputted signals. For example, the NAND circuit 33 outputs a NAND value between the voltage of the signal line d1 and the voltage of the signal line d2.

Accordingly, when the block select signal has the low level, since the signal lines d1 and d2 are fixed to a voltage (high level) after pre-charge, the output of the NAND circuit 33 is fixed to the low level.

The NOT circuit 7 is a circuit for outputting an inverted value of an inputted signal. For example, the NOT circuit 7 outputs an inverted value of the inputted block select signal.

The three-state inverter 5 is a circuit whose output terminal assumes one of a high-level state, a low-level state and a high-impedance state in response to a signal inputted thereto.

In particular, the three-state inverter 5 is a circuit whose output terminal is placed in one of a high-level state, a low-level state and a high-impedance state in response to the outputs of the NOT circuit 7 and the NAND circuit 33.

The NMOS transistor 51 performs conduction or interruption between the PMOS transistor 52 and the ground in response to the output of the NAND circuit 33 inputted to the gate thereof.

The PMOS transistor 52 performs conduction or interruption between the PMOS transistor 53 and the NMOS transistor 51 in response to the output of the NAND circuit 33 inputted to the gate thereof.

The PMOS transistor 53 performs conduction or interruption between the power supply and the PMOS transistor 52 in response to the output of the NOT circuit 7 inputted to the gate thereof.

When the signal inputted to the gate of the PMOS transistor 53 has the low level, namely, when the block select signal has the high level, the PMOS transistor 53 is placed in an on state and the NMOS transistor 51 and the PMOS transistor 52 function as a normal CMOS inverter. In other words, when the signal inputted to the gate of the PMOS transistor 53 has the low level, the three-state inverter 5 outputs a value obtained by inverting the output of the NAND circuit 33. Here, the NMOS transistor 51 is an example of a second MOS transistor and the PMOS transistor 52 is an example of a first MOS transistor. Accordingly, the CMOS inverter configured from the NMOS transistor 51 and the PMOS transistor 52 is an example of a CMOS inverter that is configured from the first MOS transistor and the second MOS transistor and that outputs a second signal using a first signal (for example, an output signal of the NAND circuit 33) as an input thereto.

In particular, when a signal having the high level is inputted to the gate of the NMOS transistor 51 and the PMOS transistor 52, the NMOS transistor 51 is placed in an on state. Accordingly, when the output capacitance of the three-state inverter 5 is discharged by the NMOS transistor 51, the three-state inverter 5 outputs a signal having the low level.

Further, when a signal having the low level is inputted to the gate of the NMOS transistor 51 and the PMOS transistor 52, the PMOS transistor 52 is placed in an on state. Accordingly, when the output capacitance of the three-state inverter 5 is charged by the PMOS transistors 52 and 53, the three-state inverter 5 outputs a signal having the high level.

On the other hand, when the signal inputted to the gate of the PMOS transistor 53 has the high level, namely, when the block select signal has the low level, the PMOS transistor 53 is placed in an off state. In other words, the PMOS transistor 53 is an example of a third MOS transistor that is placed in an off state when a control signal (for example, a block select signal) for controlling the output of the second signal is inputted to the gate terminal thereof and indicates inhibition of outputting of the second signal. When a low-level signal is inputted to the gate of the NMOS transistor 51 and the gate of the PMOS transistor 52, then since the NMOS transistor 51 is placed in an off state, the output terminal of the three-state inverter 5 is placed in a high-impedance state. In particular, when the NMOS transistor 51 and the PMOS transistor 53 are placed in an off state, the output terminal of the three-state inverter 5 is placed in a high-impedance state.

The NOT circuit 8 is a circuit for outputting an inverted value of an inputted signal. For example, the NOT circuit 8 outputs a value obtained by inverting the output of the three-state inverter 5 inputted thereto.

Now, operation of the entire dynamic select circuit according to the first embodiment is described.

As an example, a case is described in which the Data signal 11 inputted to the NMOS transistor N2 of the block 11 included in the dynamic block 4-1 is selected and outputted.

First, when the signal φ has the low level, namely, within a pre-charge period, since the PMOS transistors P1 and P3 and the NMOS transistors N3 and N6 are placed in an on state and an off state, respectively, the voltages of the signal lines d1 and d2 are placed in a high-level state. Since the voltages of the signal lines d1 and d2 are placed in the high level, the output of the NAND circuit 33 is placed in a low-level state and the PMOS transistors P2 and P4 are placed in an on state.

It is to be noted that, when the voltages of the signal lines d1 and d2 are placed in a low-level state within a period within which the signal φ has the high level, the voltages of the signal lines d1 and d2 cannot be returned to the high-level state within the period within which the signal φ has the high level. Therefore, for example, select 11 to select mn and Data 11 to Data mn are not varied within the period within which the signal φ has the high level.

Accordingly, within the pre-charge period, the output signals select 11 to select mn and Data 11 to Data mn of the AND circuits 2 and 3 are settled.

Thereafter, when the signal φ is placed into a high-level state and the time period enters an evaluation period, then the PMOS transistors P1 and P3 and the NMOS transistors N3 and N6 are placed into an off state and an on state, respectively. Accordingly, the voltage of the signal line d1 comes to have a value corresponding to the output signal of the AND circuit 2 and the Data signal inputted to the NMOS transistor N2. Further, the voltage of the signal line d2 comes to have a value corresponding to the output signal of the AND circuit 3 and the Data signal inputted to the NMOS transistor N5.

For example, a case is considered in which the Data signal 11, block select signal 1 and select signal <1> have the high level and the sel signal has the low level, respectively. In this case, the output of the AND circuit 2 connected to the dynamic block 4-1 to the gate of the NMOS transistor N1 provided in the sub block bit of the dynamic block 4-1 is placed into a high-level state. Accordingly, the NMOS transistors N1 to N3 provided in the sub block bit of the dynamic block 4-1 are placed into an on state and the voltage of the signal line d1 of the dynamic block 4-1 is placed into a low-level state. Further, the output of the AND circuit 2 connected to the dynamic block 4-1 to the gate of the NMOS transistor N1 provided in each of the sub blocks b12 to b1n of the dynamic block 4-1 is placed into a low-level state. This is because the select signal is a not signal. Accordingly, the NMOS transistor N1 provided in each of the sub blocks b12 to b1n of the dynamic block 4-1 is placed into an off state.

On the other hand, since the sel signal has the low level, the output of the AND circuit 3 connected to the dynamic block 4-1 is placed in a low-level state. Accordingly, since the NMOS transistor N4 provided in the sub block b2 of the dynamic block 4-1 is placed in an off state, the voltage of the signal line d2 maintains the high level.

By the operation described above, a low-level signal and a high-level signal are inputted to the NAND circuit 33 provided in the dynamic block 4-1. Then, the NAND circuit 33 provided in the dynamic block 4-1 outputs a high-level signal to the gate of the NMOS transistor 51 and the PMOS transistor 52 provided in the three-state inverter 5-1.

Accordingly, since the NMOS transistor 51 is placed into an on state to discharge the output capacitance of the three-state inverter 5-1 by the NMOS transistor 51, the three-state inverter 5-1 outputs a low-level signal.

It is to be noted that, since the block select signal 1 has the high level, the output of the NOT circuit 7 connected to the three-state inverter 5-1 is placed in a low-level state and the PMOS transistor 53 configuring the three-state inverter 5-1 is placed in an on state. Accordingly, for example, when the Data signal 11 has the low level, the three-state inverter 5-1 outputs a high-level signal because the PMOS transistors 52 and 53 are placed in an on state.

It is to be noted that, since the block select signals 2 to (m/2) have the low level, the outputs of the AND circuits 2 and 3 connected to the dynamic blocks 4-2 to 4-(m/2) are placed in a low-level state. Accordingly, the NMOS transistors N1 and N4 provided in the dynamic blocks 4-2 to 4-(m/2) are placed in an off state. Therefore, the voltages of the signal lines d1 and d2 provided in the dynamic blocks 4-2 to 4-(m/2) maintain the high level.

Accordingly, only the high-level signal is inputted to the NAND circuits 33 provided in the dynamic blocks 4-2 to 4-(m/2). The NAND circuits 33 provided in the dynamic blocks 4-2 to 4-(m/2) output low-level signals to the three-state inverters 5-2 to 5-(m/2), respectively. In other words, the selection unit determines an output thereof in response to the outputs of the AND circuits. In particular, the output of the NAND circuit 33 to the three-state inverter 5 is fixed to the low level by the block select signal. In other words, the input of the three-state inverter 5 is fixed to the low level by the block select signal. In particular, the AND circuits 2 and 3 are an example of a fixing unit for fixing a value of the first signal based on the control signal. More particularly, the AND circuits 2 and 3 are an example of a fixing unit for fixing the output of the selection unit to fix the value of the first signal.

Accordingly, the NMOS transistor 51 provided in each of the three-state inverters 5-2 to 5-(m/2) is placed in an on state. In particular, the AND circuits 2 and 3 are an example of a fixing unit for fixing the first signal to a value with which the second transistor is placed in an off state where the source terminal of the second MOS transistor is connected to the second power supply when the control signal indicates inhibition of outputting of the second signal.

It is to be noted that, since the block select signals 22 to (m/2) have the low level, a high-level signal is inputted to the gate of the PMOS transistor 53 included in the three-state inverters 5-2 to 5-m.

Accordingly, the PMOS transistor 53 included in the three-state inverters 5-2 to 5-(m/2) is placed in an off state.

In particular, when the block select signals 2 to (m/2) have the low level, the NMOS transistor 51 and the PMOS transistor 53 included in the three-state inverters 5-2 to 5-(m/2) are placed in an off state. Accordingly, the outputs of the three-state inverters 5-2 to 5-(m/2) are placed in a high-impedance state. In particular, since the input to the three-state inverter is fixed to the low level using the block select signal, the high-impedance state is implemented by the three MOS transistors.

Accordingly, a low-level signal is inputted from the three-state inverter 5-1 to the NOT circuit 8, and the NOT circuit 8 outputs a high-level signal. In particular, the NOT circuit 8 outputs the Data signal 11.

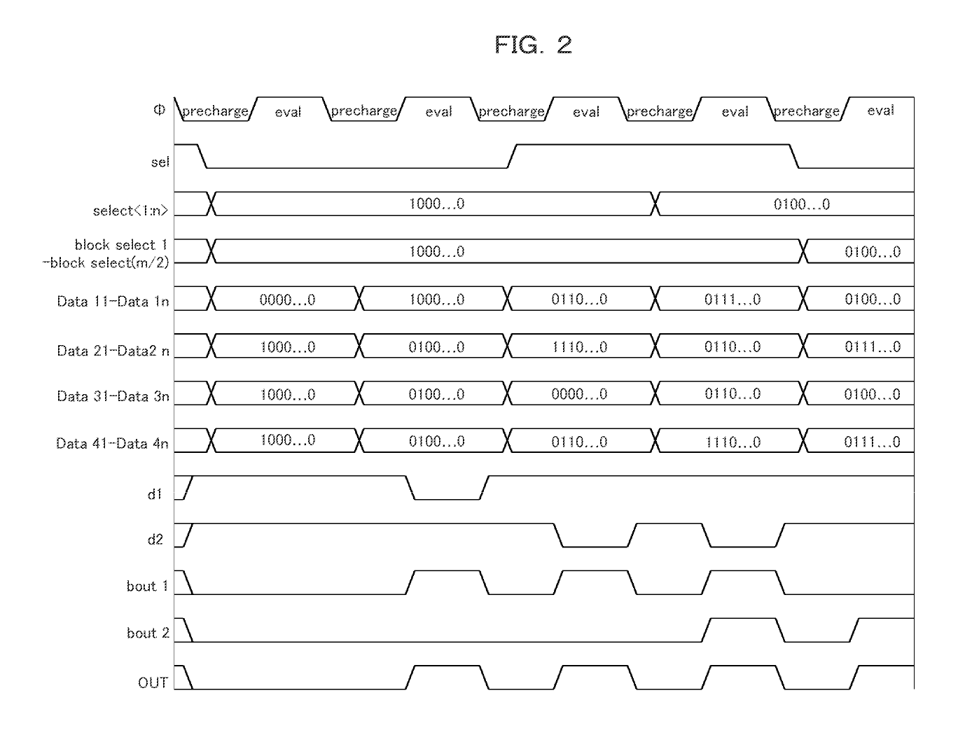

In the example of the first embodiment, the block select signal is inputted to the corresponding AND circuits 2 and 3 as described above. Then, the NMOS transistors N1 and N4 are controlled by the outputs of the AND circuits 2 and 3 to which the block select signal is inputted thereby to control the output of the dynamic block. In particular, when the block select signal has the high level, the dynamic block 4 outputs a value corresponding to the Data signal. However, when the block select signal has the low level, since the NMOS transistors N1 and N4 are placed in an off state, the output of the dynamic block 4 is fixed to the low level irrespective of the Data signal. In other words, when the block select signal has the low level, the input of the three-state inverter 5 is fixed to the low level (refer to bout 2 in the first evaluation period in the time chart depicted in FIG. 2). The input to the three-state inverter 5 is fixed to the low level to place the output of the three-state inverter 5 in a high-impedance state.

In this manner, with the example of the first embodiment, when the block select signal has the low level, since the input to the three-state inverter 5 to which the block select signal is inputted is fixed, the three-state inverter can be configured from three MOS transistors. Further, since one NMOS transistor is provided between the output terminal of the three-state inverter 5 and the ground, the speed for discharging the output capacitance of the three-state inverter 5 can be increased. In other words, with the three-state inverter 5 according to the first embodiment, the speed of operation when a low-level signal is outputted can be increased. It is to be noted that, in the dynamic selector circuit 1, the operation speed for outputting a value after pre-charge as it is, namely, the speed of operation for outputting the high level, is originally high.

Further, with the first embodiment, since the three-state inverter 5 is configured from the three MOS transistors, low power consumption can be implemented in comparison with the conventional three-state inverter configured from four MOS transistors.

### [B] Second Embodiment

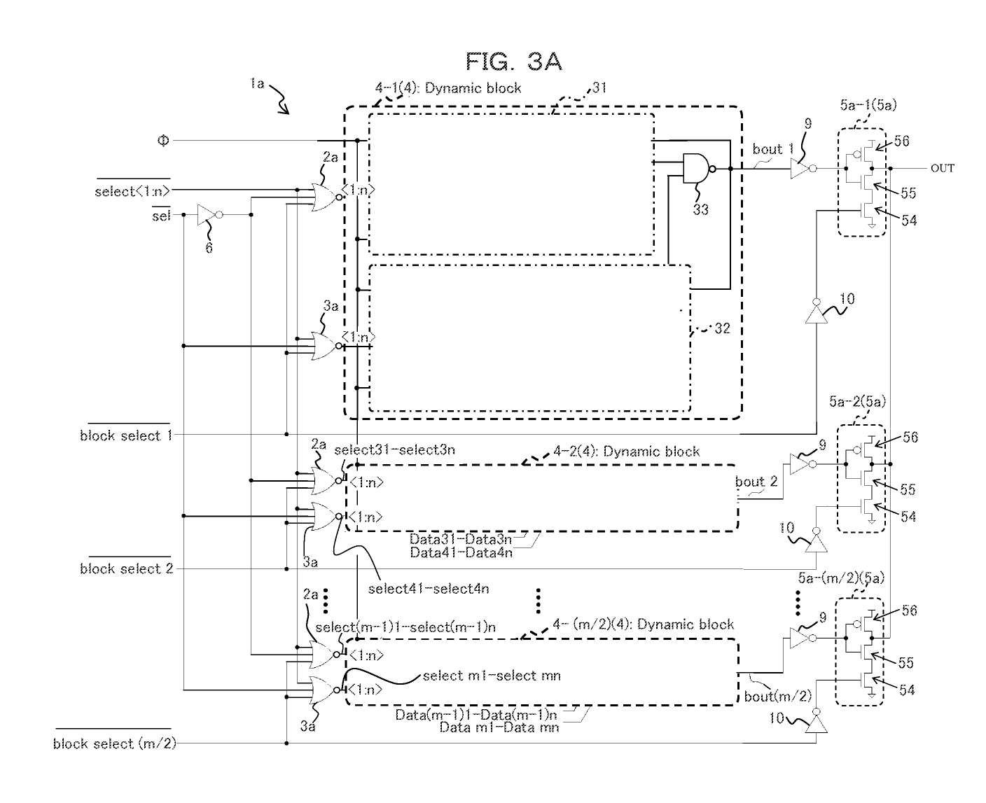

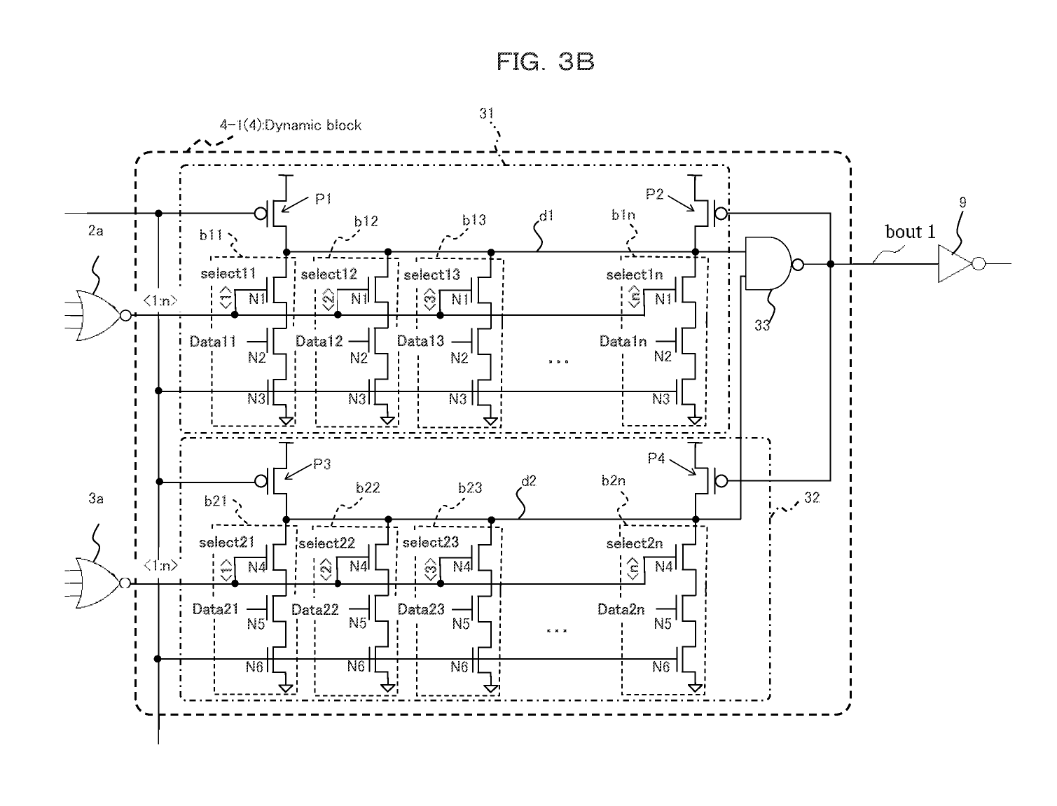

FIG. 3A is a view depicting a configuration of a dynamic selector circuit as an example of the embodiment. FIG. 3B is a view depicting a configuration of a dynamic block of the dynamic selector circuit as the example of the embodiment.

As depicted in FIGS. 3A and 3B, the dynamic select circuit 1a according to the second embodiment includes a NOR circuit 2a, another NOR circuit 3a, dynamic blocks 4-1 to 4-(m/2), three-state inverters 5a-1 to 5a-(m/2), a NOT circuit 6, another NOT circuit 9 and a further NOT circuit 10.

The NOT circuits 9 and 10 are provided in each of the dynamic blocks 4-1 to 4-(m/2). The NOR circuits 2a and 3a are provided in each of the dynamic blocks 4-1 to 4-(m/2).

In the following description, as a reference character for indicating a three-state inverter, one of reference characters 5a-3 to 5a-m is used when it is intended to specify one of the plurality of three-state inverters. However, a reference character 5a is used when an arbitrary three-state inverter is designated.

It is to be noted that, since each of the dynamic blocks 4-3 to 4-(m−2)/2 has a configuration similar to that of the dynamic block 4-1, for the convenience of illustration, illustration of the dynamic blocks 4-3 to 4-(m−2)/2 is omitted in FIG. 3A.

Since the three-state inverters 5a-3 to 5a-(m−2)/2 individually have a configuration similar to that of the three-state inverter 5a-1, for the convenience of illustration, illustration of the three-state inverters 5a-3 to 5a-(m−2)/2 is omitted in FIG. 3A.

Further, in FIG. 3A, illustration of the NOT circuits 9 and 10 connected individually to the three-state inverters 5a-3 to 5a-(m−2)/2 and the NOR circuits 2a and 3a connected to the dynamic blocks 4-3 to 4-(m−2)/2 is omitted.

Further, since the dynamic blocks 4-2 and 4-(m/2) individually have a configuration similar to that of the dynamic block 4-1, for the convenience of illustration, a detailed configuration of the dynamic blocks 4-2 and 4-(m/2) is omitted in FIG. 3A.

The dynamic selector circuit 1a according to the second embodiment includes the NOR circuits 2a and 3a in place of the AND circuits 2 and 3 in the dynamic selector circuit 1 according to the first embodiment. Further, the other components of the dynamic selector circuit 1a are configured similarly as in the dynamic selector circuit 1 according to the first embodiment.

It is to be noted that, since like or substantially like elements to those in FIG. 3 are denoted by like reference characters, detailed description is omitted.

Further, different from the dynamic selector circuit 1 according to the first embodiment, values obtained by inverting the select signal, sel signal and block select signal are inputted to the dynamic selector circuit 1a.

Further, in the dynamic selector circuit 1a according to the second embodiment, the configuration of the three-state inverter is different in comparison with the dynamic selector circuit 1 according to the first embodiment.

Further, the dynamic selector circuit 1a according to the second embodiment is different in comparison with the dynamic selector circuit 1 according to the first embodiment in that the NOT circuit 9 is connected to the output of the NAND circuit 33.

Further, the dynamic selector circuit 1a according to the second embodiment is different in comparison with the dynamic selector circuit 1 according to the first embodiment in that the NOT circuit 10 to which an inverted block select signal is inputted is provided.

A connection relationship of the components is described below.

To the dynamic selector circuit 1a, values obtained by inverting the sel signal, select signal <1:n> and block select signals 1 to (m/2) are inputted and Data signals 11 to mn and the signal φ are inputted.

An inverted sel signal is inputted to the NOT circuit 6, and the output of the NOT circuit 6 is connected to the input of the NOR circuit 2a.

The output of the NOT circuit 6 is connected to an input of the NOR circuit 2a and the output of the NOR circuit 2a is connected to the dynamic block 4. Further, an inverted select signal and a signal obtained by inverting the block select signal corresponding to the dynamic block 4 to which the NOR circuit 2a is connected are inputted to the NOR circuit 2a.

The output of the NOR circuit 3a is connected to the dynamic block 4. An inverted sel signal, an inverted select signal and a signal obtained by inverting the block select signal corresponding to the dynamic block 4 to which the NOR circuit 3a is connected are inputted to the inputs of the NOR circuit 3a.

To the dynamic block 4, the outputs of the NOR circuits 2a and 3a are connected and the signal φ for changeover control between a pre-charge period and an evaluation period is inputted. Further, a plurality of Data signals is inputted to the dynamic block 4. Further, the output of the dynamic block 4 is connected to the corresponding three-state inverter 5a.

The input of the NOT circuit 9 is connected to the output of the NAND circuit 33, and the output of the NOT circuit 9 is connected to the three-state inverter 5a. More particularly, the output of the NOT circuit 9 is connected to the gate of an NMOS transistor 55 and a PMOS transistor 56 hereinafter described and configuring the three-state inverter 5a.

An inverted block select signal is inputted to the NOT circuit 10. Further, the output of the NOT circuit 10 is connected to the gate of an NMOS transistor 54 configuring the three-state inverter 5a.

The output of the NOT circuit 9 and the output of the NOT circuit 10 are connected to the three-state inverter 5a. Further, the outputs of the three-state inverters 5a-1 to 5a-(m/2) are connected to each other.

The three-state inverter 5a includes the NMOS transistor 54, NMOS transistor 55 and PMOS transistor 56.

The drain of the NMOS transistor 54 is connected to the source of the NMOS transistor 55. Further, the source of the NMOS transistor 54 is grounded. Further, the gate of the NMOS transistor 54 is connected to the output of the NOT circuit 10.

The drain and the source of the NMOS transistor 55 are connected to the drain of the PMOS transistor 56 and the drain of the NMOS transistor 54, respectively. The gate of the NMOS transistor 55 is connected to the gate of the PMOS transistor 56 and is connected to the output of the NOT circuit 9.

The drain and the source of the PMOS transistor 56 are connected to the drain of the NMOS transistor 55 and the power supply, respectively. Further, the gate of the PMOS transistor 56 is connected to the gate of the NMOS transistor 55 and is connected to the output of the NOT circuit 9.

In particular, the NMOS transistor 55 and the PMOS transistor 56 configure a CMOS inverter, and the CMOS inverter is cascade-connected to the NMOS transistor 54.

In particular, the NMOS transistor 55 (an example of the second MOS transistor) and the PMOS transistor 56 (an example of the first MOS transistor) configure the CMOS inverter. The CMOS inverter is cascade-connected to the NMOS transistor 54 (an example of the third MOS transistor) between the power supply (first power supply) and the ground (second power supply). In other words, the three-state inverter 5a is an example of an outputting unit in which the CMOS inverter and the third MOS transistor are cascade-connected between the first power supply and the second power supply that supplies a lower voltage than that of the first power supply.

It is to be noted that the drain of the NMOS transistor 55 and the drain of the PMOS transistor 56 serve as the output of the three-state inverter 5a. Further, the gate of the NMOS transistor 55 and the gate of the PMOS transistor 56 are used as the inputs to the three-state inverter 5a.

Now, functions of the components are described.

The NOR circuit 2a is a circuit for outputting a NOR value of inputted signals. For example, the NOR circuit 2a outputs a NOR value among an inverted select signal, a sel signal outputted from the NOT circuit 6 and an inverted block select signal.

The NOR circuit 3a is a circuit for outputting a NOR value of inputted signals. For example, the NOR circuit 3a outputs a NOR value among an inverted select signal, an inverted sel signal and an inverted block select signal.

The NOT circuit 6 is a circuit for outputting a value obtained by inverting an inputted signal. For example, the NOT circuit 6 outputs a value obtained by inverting an inputted inverted sel signal.

The NOT circuit 10 is a circuit for outputting a value obtained by inverting an inputted signal. For example, the NOT circuit 10 outputs a value obtained by inverting an inputted inverted block select signal.

The NOT circuit 9 is a circuit for outputting a value obtained by inverting an inputted signal. For example, the NOT circuit 9 outputs a value obtained by inverting the output of the NAND circuit 33.

The three-state inverter 5a is a circuit whose output terminal assumes one of a high-level state, a low-level state and a high-impedance state in response to a signal inputted thereto.

The NMOS transistor 54 performs conduction or interruption between the NMOS transistor 55 and the ground in response to the output of the NOT circuit 10 inputted to the gate thereof.

The NMOS transistor 55 performs conduction or interruption between the PMOS transistor 56 and the NMOS transistor 54 in response to the output of the NOT circuit 9 inputted to the gate thereof.

The PMOS transistor 56 performs conduction or interruption between the power supply and the NMOS transistor 55 in response to the output of the NOT circuit 9 inputted to the gate thereof.

When the signal inputted to the gate of the NMOS transistor 54 has the high level, namely, when the block select signal has the high level, the NMOS transistor 54 is placed in an on state and the NMOS transistor 55 and PMOS transistor 56 function as a normal CMOS inverter. In other words, when the signal inputted to the gate of the NMOS transistor 54 has the high level, the three-state inverter 5a outputs a value obtained by inverting the output of the NOT circuit 9. Here, the NMOS transistor 55 is an example of the second MOS transistor and the PMOS transistor 56 is an example of the first MOS transistor. Accordingly, the CMOS inverter configured from the NMOS transistor 55 and the PMOS transistor 56 is an example of the CMOS inverter that outputs a second signal using a first signal (for example, an output signal of the NOT circuit 9) as an input thereto and which is configured from the first MOS transistor and the second MOS transistor.

In particular, when a low-level signal is inputted to the gates of the NMOS transistor 55 and the PMOS transistor 56, the PMOS transistor 56 is placed in an on state. Accordingly, the output capacitance of the three-state inverter 5a is charged by the PMOS transistor 56, and consequently, the three-state inverter 5a outputs a high-level signal.

However, when a high-level signal is inputted to the gate of the NMOS transistor 55 and the PMOS transistor 56, the NMOS transistor 55 is placed in an on state. Accordingly, the output capacitance of the three-state inverter 5a is discharged by the NMOS transistors 54 and 55, and consequently, the three-state inverter 5a outputs a low-level signal.

On the other hand, when the signal inputted to the gate of the NMOS transistor 54 has the low level, namely, when the block select signal has the low level, the NMOS transistor 54 is placed in an off state. In other words, the NMOS transistor 54 is an example of the third MOS transistor to the gate terminal of which a control signal (for example, a block select signal) for controlling an output of the second signal is inputted and which is placed in an off state when the control signal indicates inhibition of outputting of the second signal. If a high-level signal is inputted to the gate of the NMOS transistor 55 and the gate of the PMOS transistor 56, then since the PMOS transistor 56 is placed into an off state, the output terminal of the three-state inverter 5a is placed into an high-impedance state. In other words, as the NMOS transistor 54 and the PMOS transistor 56 are placed into an off state, the output terminal of the three-state inverter 5a is placed into a high-impedance state.

Now, operation of the entire dynamic select circuit according to the second embodiment is described.

As an example, a case is described in which Data 11 inputted to the NMOS transistor N2 of the block 11 included in the dynamic block 4-1 is selected and outputted.

First, when the signal φ has the low level, namely, within a pre-charge period, the PMOS transistors P1 and P3 and the NMOS transistors N3 and N6 are placed in an on state and an off state, respectively. Therefore, the voltages of the signal lines d1 and d2 have the high level. Since the voltages of the signal lines d1 and d2 are placed in a high-level state, the output of the NAND circuit 33 are placed in the low level and the PMOS transistors P2 and P4 are placed in an on state.

Thereafter, when the signal φ changes to the high level and an evaluation period starts, then the PMOS transistors P1 and P3 and the NMOS transistors N3 and N6 are placed into an off state and an on state, respectively. Accordingly, the voltage of the signal line d1 comes to have a value corresponding to the output signal of the NOR circuit 2a and the Data signal inputted to the NMOS transistor N2. Further, the voltage of the signal line d2 comes to have a value corresponding to the output signal of the NOR circuit 3a and the Data signal inputted to the NMOS transistor N5.

For example, a case is considered in which the Data signal 11, block select signal 1 and select signal <1> have the high level and the sel signal has the low level. In this case, the output of the NOR circuit 2a connected to the dynamic block 4-1 to the gate of the NMOS transistor N1 provided in the sub block b11 of the dynamic block 4-1 has the high level. Accordingly, the NMOS transistors N1 to N3 provided in the sub block b11 of the dynamic block 4-1 are placed in an on state and the voltage of the signal line d1 of the dynamic block 4-1 is placed in a low-level state. Further, the output of the NOR circuit 2a connected to the dynamic block 4-1 to the gate of the NMOS transistor N1 provided in the sub blocks b12 to b1n of the dynamic block 4-1 is in a low-level state. This is because the select signal is a shot signal. Accordingly, the NMOS transistor N1 provided in the sub blocks b12 to b1n of the dynamic block 4-1 is placed in an off state.

On the other hand, since the sel signal has the low level, the output of the NOR circuit 3a connected to the dynamic block 4-1 is placed in a low-level state. Accordingly, since the NMOS transistor N4 of the sub block b2 of the dynamic block 4-1 is placed in an off state, the voltage of the signal line d2 maintains the high level.

Accordingly, a low-level signal and a high-level signal are inputted to the NAND circuit 33 provided in the dynamic block 4-1. Thus, the NAND circuit 33 provided in the dynamic block 4-1 outputs a high-level signal to the NOT circuit 9.

The NOT circuit 9 outputs a low-level signal to the gate of the NMOS transistor 55 and the PMOS transistor 56 that configure the three-state inverter 5a-1.

Accordingly, the PMOS transistor 56 is placed into an on state to charge the output capacitance of the three-state inverter 5a-1 by the PMOS transistor 56, and consequently, the three-state inverter 5a-1 outputs a high-level signal.

It is to be noted that, since the block select signal 1 has the high level, the output of the NOT circuit 10 connected to the three-state inverter 5a-1 is placed in a high-level state and the NMOS transistor 54 configuring the three-state inverter 5a-1 is placed in an on state. Accordingly, for example, when the Data signal 11 has the low level, since the NMOS transistor 54 is placed in an on state, the three-state inverter 5a-1 outputs a high-level signal.

Further, since the block select signals 2 to (m/2) individually have the low level, the outputs of the NOR circuit 2a and 3a connected individually to the dynamic blocks 4-2 to 4-(m/2) are placed in a low-level state. Accordingly, the NMOS transistors N1 and N4 provided in the dynamic blocks 4-2 to 4-(m/2) are placed in an off state. Therefore, the voltages of the signal lines d1 and d2 provided in the dynamic blocks 4-2 to 4-(m/2) maintain the high level.

Accordingly, only the high-level signals are inputted to the NAND circuit 33 provided individually in the dynamic blocks 4-2 to 4-(m/2). Then, the NAND circuit 33 provided individually in the dynamic blocks 4-2 to 4-(m/2) outputs a low-level signal to the corresponding NOT circuit 9. Then, the NOT circuit 9 connected individually to the dynamic blocks 4-2 to 4-(m/2) outputs a high-level signal to the three-state inverters 5a-2 to 5a-(m/2). In particular, the selection unit determines the output thereof in response to the output of the NOR circuit. As viewed from a different viewpoint, the output of the NOT circuit 9 to the three-state inverter 5a is fixed to the high level by the block select signal. In other words, the input to the three-state inverter 5a is fixed to the high level by the block select signal. In particular, the NOR circuits 2a and 3a are an example of a fixing unit for fixing the value of the first signal based on the control signal. More particularly, the NOR circuits 2a and 3a are an example of a fixing unit for fixing the output of the selection unit thereby to fix the value of the first signal.

Accordingly, the PMOS transistor 56 provided in three-state inverters 5a-2 to 5a-(m/2) is placed in an off state. In particular, the NOR circuits 2a and 3a are an example of a fixing unit in which, where the source terminal of the first MOS transistor is connected to the first power supply when the control signal indicates inhibition of outputting of the second signal, the first signal is fixed to a value with which the first transistor is placed in an off state.

It is to be noted that, since the block select signals 2 to (m/2) individually have the low level, a low-level signal is inputted to the gate of the NMOS transistor 54 included in the three-state inverters 5a-2 to 5a-(m/2).

Accordingly, the NMOS transistor 54 included in the three-state inverters 5a-2 to 5a-(m/2) is placed in an off state.

In particular, when the block select signals 2 to (m/2) individually have the low level, the NMOS transistor 54 and PMOS transistor 56 included in the three-state inverters 5a-2 to 5a-(m/2) are placed in an off state. Accordingly, the output of the three-state inverters 5a-2 to 5a-(m/2) is placed in a high-impedance state. In particular, since the input to the three-state inverter is fixed to the high level using the block select signal, the high-impedance state is implemented by the three MOS transistors.

Accordingly, a high-level signal is outputted from the output of the dynamic selector circuit 1a. In particular, the dynamic selector circuit 1a outputs the Data 11.

In the example of the second embodiment, the inverted block select signal is inputted to the NOR circuits 2a and 3a as described above. Further, the NMOS transistors N1 and N4 are controlled based on the outputs of the NOR circuits 2a and 3a to which the inverted block select signal is inputted thereby to control the output of the dynamic block. In particular, when the block select signal has the high level, the dynamic block 4 outputs a value corresponding to the Data signal. However, when the block select signal has the low level, the NMOS transistors N1 and N4 are placed in an off state. Therefore, the output of the dynamic block 4 is fixed to the low level irrespective of the Data signal. In other words, when the block select signal has the low level, the input to the three-state inverter 5a is fixed to the high level. When the input to the three-state inverter 5a is fixed to the high level, then the output of the three-state inverter 5a is placed in a high-impedance state.

In this manner, with the second embodiment, when the block select signal has the low level, the input to the three-state inverter 5a to which the block select signal is inputted is fixed. Therefore, the three-state inverter can be configured from three MOS transistors. Further, since one PMOS transistor is provided between the output terminal of the three-state inverter 5a and the power supply, the speed for charging the output capacitance of the three-state inverter 5a can be increased. In particular, with the three-state inverter 5a according to the second embodiment, the speed of operation when a high-level signal is outputted can be increased. It is to be noted that, in the dynamic selector circuit 1a, the operation speed for outputting a value after pre-charge as it is, namely, the operation speed for outputting the low level, is high in the first place.

Further, with the second embodiment, since the three-state inverter 5a is configured from three MOS transistors, low power consumption can be implemented in comparison with the conventional three-state inverter configured from four MOS transistors.

### [C] Third Embodiment

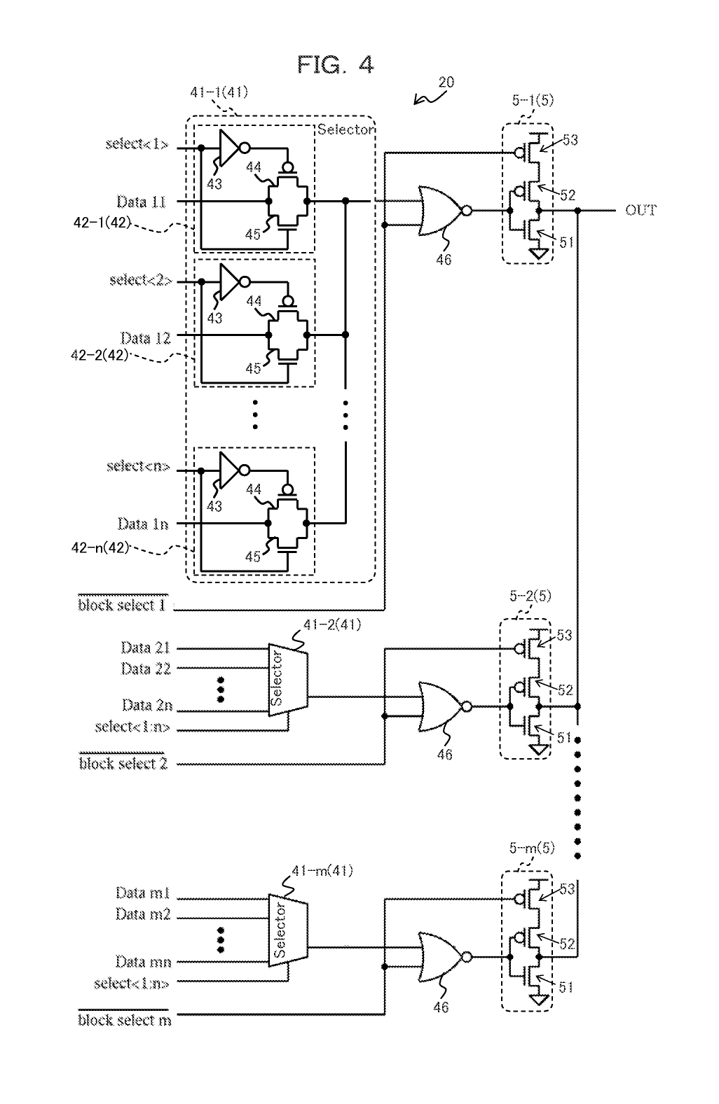

FIG. 4 is a view depicting a configuration of a static selector circuit as an example of the embodiment. The static selector circuit 20 depicted in FIG. 4 is an m×n:1 static selector circuit. It is to be noted that “n” indicates the number of blocks 42 hereinafter described and “m” indicates the number of selectors 41 hereinafter described and included in the dynamic selector circuit 1.

As depicted in FIG. 4, the static selector circuit 20 according to the third embodiment includes selectors 41-1 to 41-m, a NOR circuit 46 and three-state inverters 5-1 to 5-m.

The three-state inverters 5-1 to 5-m are provided corresponding to the selectors 41-1 to 41-m, respectively. Further, the NOR circuit 46 is provided in each of the selectors 41-1 to 41-m.

In the following description, as a reference character for indicating a selector, one of the reference characters 41-1 to 41-m is used when it is intended to specify one of the plurality of selectors. However, the reference character 41 is used when an arbitrary selector is designated.

Further, as a reference character for indicating a three-state inverter, one of the reference characters 5-3 to 5-m is used when it is intended to specify one of the plurality of three-state inverters. However, the reference character 5 is used when an arbitrary selector is designated.

It is to be noted that, since the selectors 41-3 to 41-(m−1) have a configuration similar to that of the selector 41-1, for the convenience of illustration, illustration of the selectors 41-3 to 41-(m−1) is omitted in FIG. 4.

Further, since the three-state inverters 5-3 to 5-(m−1) have a configuration similar to that of the three-state inverter 5-1, for the convenience of illustration, illustration of the three-state inverters 5-3 to 5-(m−1) is omitted in FIG. 4.

Further, illustration of the NOR circuits 46 connected to the three-state inverters 5-3 to 5-(m−1) is omitted in FIG. 4.

Further, since the selectors 41-2 and 41-m have a configuration similar to that of the selector 41-1, for the convenience of illustration, a detailed configuration of the selectors 41-1 and 41-m is omitted in FIG. 4.

It is to be noted that like or substantially like elements to those described hereinabove are denoted by like reference characters.

A connection relationship among the components is described below.

To the static selector circuit 20, the Data signals 11 to mn, select signal <1:n> and block select signals 1 to m (denoted as Data 11 to Data mn, select <1> to select <n> and block select 1 to block select m in FIG. 4, respectively) are inputted.

Further, in the following description, as a reference character for indicating a block select signal, one of reference characters 1 to m is used when it is intended to specify one of the plurality of block select signals. However, the block select signals are referred to simply as block select signal when an arbitrary block select signal is designated.

Further, the select signal is a signal indicating which one of the Data signals inputted to the selector 41 is to be outputted to the NOR circuit 46. It is to be noted that, for example, the select signal is a 1hot signal.

Further, the block select signal is provided in a corresponding relationship to each selector 41 and is a signal indicating whether or not a signal outputted from the selector 41 is to be outputted from the three-state inverter 5 corresponding to the selector 41. The block select signals 1 to m correspond to the selectors 41-1 to 41-m, respectively. Further, the block select signals 1 to m correspond to the three-state inverters 5-1 to 5-m, respectively. It is to be noted that, for example, the block select signal is a 1hot signal. For example, when the block select signal has the high level, it indicates that a signal outputted from the selector 41 is to be outputted from the corresponding three-state inverter 5. On the other hand, for example, when the block select signal has the low level, it indicates that outputting of a signal outputted from the selector 41 from the corresponding three-state inverter 5 is inhibited.

The output of the selector 41 is connected to the NOR circuit 46. Further, the select signal and the Data signal are inputted to the selector 41.

The selector 41 includes blocks 42-1 to 42-n. The blocks 42-1 to 42-n are provided corresponding to the select signals 1 to n, respectively.

In the following description, as a reference character for indicating a block, one of the reference characters 42-1 to 42-m is used when it is intended to specify one of the plurality of blocks. However, a reference character 42 is used when an arbitrary block is designated.

The block 42 is connected to an input of the NOR circuit 46. Further, the select signal and the Data signal are inputted to the block 42.

The block 42 includes a NOT circuit 43, a PMOS transistor 44 and an NMOS transistor 45.

The output of the NOT circuit 43 is connected to the gate of the PMOS transistor 44. Further, the select signal is inputted to an input of the NOT circuit 43.

The output of the NOT circuit 43 is connected to the gate of the PMOS transistor 44. Further, the drain (or source) of the PMOS transistor 44 is connected to the input of the NOR circuit 46 and the source (or drain) of the NMOS transistor 45. Further, to the source (or drain) of the PMOS transistor 44, the drain (or source) of the NMOS transistor 45 is connected and the Data signal is inputted.

The source (or drain) of the NMOS transistor 45 is connected to an input of the NOR circuit 46 and the drain (or source) of the PMOS transistor 44. Further, the drain (or source) of the NMOS transistor 45 is connected to the source (or drain) of the PMOS transistor 44 and the Data signal is inputted to the drain (or source) of the NMOS transistor 45. Further, the select signal is inputted to the gate of the NMOS transistor 45.

In other words, the PMOS transistor 44 and the NMOS transistor 45 configure a CMOS switch for controlling whether or not the Data signal is to be inputted to the NOR circuit 46.

An input and the output of the NOR circuit 46 are connected to the output of the selector 41 and an input of the three-state inverter 5, respectively. In particular, the output of the NOR circuit 46 is connected to the NMOS transistor 51 and the PMOS transistor 52 which configure the three-state inverter 5. Further, an inverted block select signal is inputted to the NOR circuit 46. It is to be noted that the inverted block select signal is inputted also to the gate of the PMOS transistor 53 configuring the three-state inverter 5.

Now, functions of the components are described.

The selector 41 outputs one of a plurality of inputted Data signals to the NOR circuit 46 in response to the select signal. In particular, the selector 41 is an example of a selection unit for outputting one of a plurality of inputted Data signals in response to a selection signal (for example, the select signal).

The block 42 outputs the inputted Data signal in response to the select signal. For example, when the select signal has the high level, the block 42 outputs the inputted Data signal. On the other hand, when the select signal has the low level, the block 42 inhibits outputting of the Data signal.

The NOT circuit 43 is a circuit for outputting a value obtained by inverting an inputted signal. For example, the NOT circuit 43 outputs the inverted select signal to the gate of the NMOS transistor 45.

The PMOS transistor 44 performs conduction or interruption between the drain and the source thereof in response to the output of the NOT circuit 43 inputted to the gate thereof.

The NMOS transistor 45 performs conduction and interruption between the drain and the source thereof in response to the select signal inputted to the gate thereof.

For example, when the select signal has the high level, the PMOS transistor 44 and the NMOS transistor 45 are placed in an on state, and consequently, the Data signal is outputted to the NOR circuit 46. On the other hand, when the select signal has the low level, the PMOS transistor 44 and the NMOS transistor 45 are placed in an off state.

The NOR circuit 46 is a circuit for outputting a NOR value of inputted signals. For example, the NOR circuit 46 outputs a NOR value between the output of the selector 41 and the inverted block select signal. In particular, when the block select signal has the low level, the output of the NOR circuit 46 is fixed to the low level. The NOR circuit 46 is an example of a fixing unit for outputting, as the first signal, a NOR value between the output of the selection unit for outputting one of a plurality of inputted Data signals and a value obtained by inverting the control signal thereby to fix the value of the first signal.

Now, operation of the entire static select circuit according to the third embodiment is described.

As an example, a case is described in which Data 11 inputted to the selector 41-1 is selected and outputted.

For example, it is assumed that the Data signal 11, block select signal 1 and select signal <1> have the high level.

By the conditions described above, the PMOS transistor 44 and the NMOS transistor 45 of the block 42-1 of the selector 41-1 are placed in an on state and the other PMOS transistors 44 and NMOS transistors 45 provided in the selector 41-1 are placed in an off state.

Accordingly, the output of the selector 41-1 is placed in a high-level state and is inputted to the NOR circuit 46 connected to the selector 41-1.

Since the block select signal 1 has the high level, the NOR circuit 46 connected to the selector 41-1 outputs a low-level signal to the gate of the NMOS transistor 51 and the PMOS transistor 52 that configure the three-state inverter 5-1.

Accordingly, the NMOS transistor 51 is placed in an on state and discharges the output capacitance of the three-state inverter 5-1, and consequently, the three-state inverter 5-1 outputs a low-level signal.

It is to be noted that, since the block select signal 1 has the high level, the PMOS transistor 53 configuring the three-state inverter 5-1 is placed in an on state. Accordingly, for example, when the Data signal 11 has the low level, the PMOS transistors 52 and 53 are placed in an on state, and consequently, the three-state inverter 5-1 outputs a high-level signal.

On the other hand, the outputs of the selectors 41-2 to 41-m are inputted to the corresponding NOR circuits 46.

Here, since the block select signals 2 to m have the low level, a high-level signal is inputted to the NOR circuits 46 connected to the selectors 41-2 to 41-m.

Accordingly, irrespective of the outputs from the selectors 41-2 to 41-m, the NOR circuit 46 connected individually to the selectors 41-2 to 41-m outputs a low-level signal to the three-state inverters 5-2 to 5-m. In particular, the input signal to the three-state inverter is fixed to the low level by the block select signal. In other words, the output of the NOR circuit 46 is fixed to the low level by the block select signal.

Accordingly, the NMOS transistor 51 provided in the three-state inverters 5-2 to 5-m is placed in an off state.

It is to be noted that, since the block select signals 2 to m have the low level, a high-level signal is inputted to the gate of the PMOS transistor 53 provided in the three-state inverters 5-2 to 5-m, and consequently, the PMOS transistor 53 is placed in an off state.

In particular, when the block select signals 2 to m have the low level, the NMOS transistor 51 and the PMOS transistor 53 included in the three-state inverters 5-2 to 5-m are placed in an off state. Accordingly, the outputs of the three-state inverters 5-2 to 5-m are placed in a high-impedance state. In particular, since the input to the three-state inverters is fixed to the low level using the block select signal, the high-impedance state is implemented by three MOS transistors.

Accordingly, a high-level signal is outputted from the output of the static selector circuit 20. In particular, the static selector circuit 20 outputs the Data signal 11.

In the example of the third embodiment, the block select signal is inputted to the NOR circuit 46 in such a manner as described to the output to the three-state inverter 5. In particular, while the NOR circuit 46 outputs a value corresponding to the Data signal when the block select signal has the high level, when the block select signal has the low level, the output of the NOR circuit 46 is fixed to the low level irrespective of the inputted Data signal. As the input to the three-state inverter 5 is fixed to the low level, the output of the three-state inverter 5 is placed in a high-impedance state.

In this manner, with the third embodiment, when the block select signal has the low level, the input to the three-state inverter 5 to which the block select signal is inputted is fixed. Consequently, the three-state inverter can be configured from three MOS transistors. Further, since one NMOS transistor is provided between the output terminal of the three-state inverter 5 and the ground, the speed for discharging the output capacitance of the three-state inverter 5 can be increased. In other words, with the three-state inverter 5 according to the third embodiment, the speed of operation when a low-level signal is outputted can be increased.

Further, with the third embodiment, since the three-state inverter 5 is configured from three MOS transistors, low power consumption can be implemented in comparison with the conventional three-state inverter configured from four MOS transistors.

### [D] Fourth Embodiment

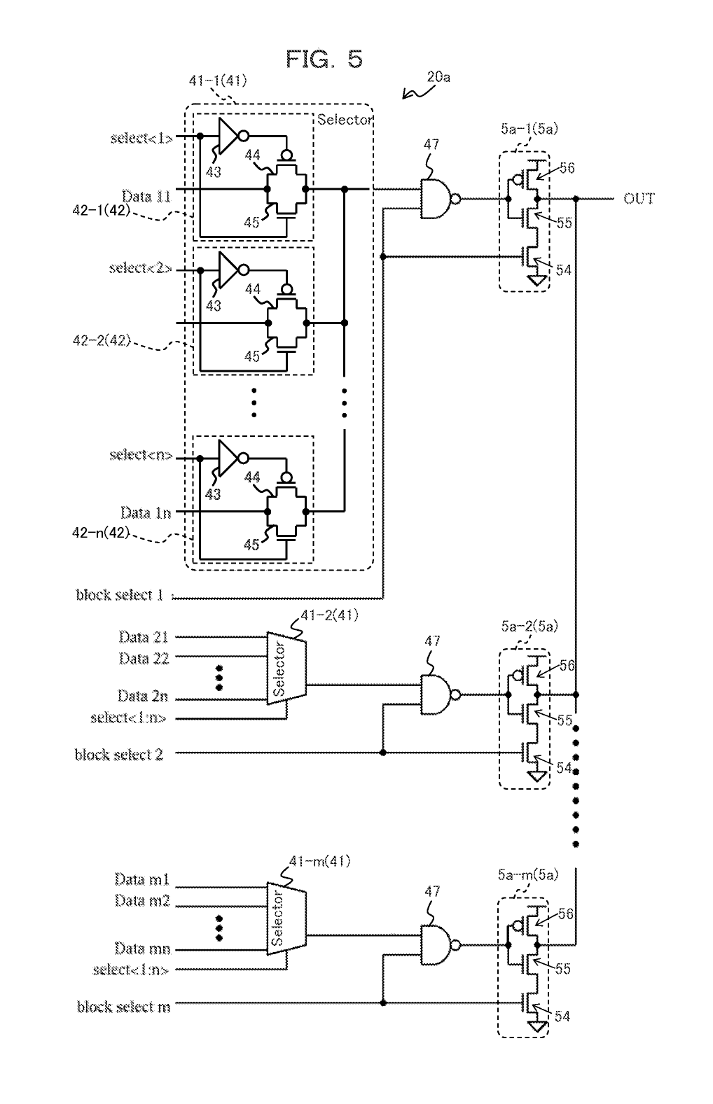

FIG. 5 is a view depicting a configuration of a static selector circuit as an example of the embodiment. The static selector circuit 20a depicted in FIG. 5 is an m×n:1 static selector circuit. It is to be noted that “n” indicates the number of blocks 42 hereinafter described and “m” indicates the number of selectors 41 hereinafter described and included in the dynamic selector circuit 1.

As depicted in FIG. 5, the static selector circuit 20a according to the fourth embodiment includes selectors 41-1 to 41-m, a NAND circuit 47 and three-state inverters 5a-1 to 5a-m.

The three-state inverters 5a-1 to 5a-m are provided corresponding to the selectors 41-1 to 41-m, respectively. Further, the NAND circuit 47 is provided in each of the selectors 41-1 to 41-m.

In the static selector circuit 20a according to the fourth embodiment, the NAND circuit 47 is provided in place of the NOR circuit 46 in the static selector circuit 20 according to the third embodiment. Further, the other part of the static selector circuit 20a is configured similarly to that of the static selector circuit 20 according to the third embodiment.

It is to be noted that, since like or substantially like elements to those described hereinabove are denoted by like reference characters, detailed description thereof is omitted. Further, to the static selector circuit 20a according to the fourth embodiment, not an inverted block select signal but a normal block select signal is inputted.

In the following description, as a reference character for indicating a selector, one of reference characters 41-1 to 41-m is used when it is intended to specify one of the plurality of selectors. However, reference character 41 is used when an arbitrary selector is designated.

Further, as a reference character for indicating a three-state inverter, one of reference characters 5a-3 to 5a-m is used when it is intended to specify one of the plurality of three-state inverters. However, reference character 5a is used when an arbitrary three-state inverter is designated.

It is to be noted that, since the selectors 41-3 to 41-(m−1) have a configuration similar to that of the selector 41-1, for the convenience of illustration, illustration of the selectors 41-3 to 41-(m−1) is omitted in FIG. 5.

Further, since the three-state inverters 5a-3 to 5a-(m−1) have a configuration similar to that of the three-state inverter 5a-1, for the convenience of illustration, illustration of the three-state inverters 5a-3 to 5a-(m−1) is omitted in FIG. 5.

Further, illustration of the NAND circuits 47 connected to the three-state inverters 5a-3 to 5a-(m−1) are omitted in FIG. 5.

Further, since the selectors 41-2 and 41-m have a configuration similar to that of the selector 4-1, for the convenience of illustration, a detailed configuration of the selectors 41-1 and 41-m is omitted in FIG. 4.

A connection relationship among the components is described below.

To the static selector circuit 20a, the Data signals 11 to mn, select signal <1:n> and block select signals 1 to m (denoted as Data 11 to Data mn, select <1> to select <n> and block select signal 1 to block select signal m in FIG. 5, respectively) are inputted.

The output of the selector 41 is connected to the NAND circuit 47. Further, the select signal and the Data signal are inputted to the selector 41.

The selector 41 includes blocks 42-1 to 42-n. The blocks 42-1 to 42-n are provided corresponding to the select signals 1 to n, respectively.

In the following description, as a reference character for indicating a block, one of reference characters 41-1 to 41-m is used when it is intended to specify one of the plurality of blocks. However, reference character 42 is used when an arbitrary block is designated.

An input and the output of the NAND circuit 47 are connected to the output of the selector 41 and an input of the three-state inverter 5a, respectively. In particular, the output of the NAND circuit 47 is connected to the gate of the NMOS transistor 55 and the PMOS transistor 56 that configure the three-state inverter 5a. Further, the block select signal is inputted to the NAND circuit 47. It is to be noted that the block select signal is inputted also to the gate of the NMOS transistor 54 configuring the three-state inverter 5a.

Now, functions of the components are described.

The selector 41 outputs one of a plurality of inputted Data signals to the NAND circuit 47 in response to the select signal.

The block 42 outputs the inputted Data signal in response to the select signal. For example, when the select signal has the high level, the block 42 outputs the inputted Data signal. On the other hand, when the select signal has the low level, the block 42 inhibits outputting of the Data signal.

The NOT circuit 43 is a circuit for outputting a value obtained by inverting an inputted signal. For example, the NOT circuit 43 outputs the inverted select signal to the gate of the PMOS transistor 45.

The PMOS transistor 44 performs conduction or interruption between the drain and the source thereof in response to the output of the NOT circuit 43 inputted to the gate thereof.

The NMOS transistor 45 performs conduction or interruption between the drain and the source thereof in response to the select signal inputted to the gate thereof.

For example, when the select signal has the high level, the PMOS transistor 44 and the NMOS transistor 45 are placed in an on state, and consequently, the Data signal is outputted to the NAND circuit 47. On the other hand, when the select signal has the low level, the MOS transistor 44 and the NMOS transistor 45 are placed in an off state.

The NAND circuit 47 is a circuit for outputting a NAND value of the inputted signal. For example, the NAND circuit 47 outputs a NAND value between the output of the selector 41 and the block select signal. In particular, when the block select signal has the low level, the output of the NAND circuit 47 is fixed to the high level. The NAND circuit 47 is an example of a fixing unit for outputting, as the first signal, a NAND value between an output of the selection unit for outputting one of a plurality of inputted Data signals and the control signal thereby to fix the value of the first signal.

Now, operation of the entire static selector circuit according to the fourth embodiment is described.

As an example, a case is described in which the Data 11 inputted to the selector 41-1 is selected and outputted.

For example, it is assumed that the Data signal 11, block select signal 1 and select signal <1> have the high level.

By the conditions described above, the PMOS transistor 44 and the NMOS transistor 45 of the block 42-1 of the selector 41-1 are placed in an on state and the other PMOS transistors 44 and the NMOS transistors 45 provided in the selector 41-1 are placed in an off state.

Accordingly, the output of the selector 41-1 is placed in a high-level state and is inputted to the NAND circuit 47 connected to the selector 41-1.

Since the block select signal 1 has the high level, the NAND circuit 47 connected to the selector 41-1 outputs a low-level signal to the gate of the NMOS transistor 55 and the PMOS transistor 56 configuring the three-state inverter 5a-1.

Accordingly, the PMOS transistor 56 is placed in an on state and charges the output capacitance of the three-state inverter 5a-1, and consequently, the three-state inverter 5a-1 outputs a high-level signal.

It is to be noted that, since the block select signal 1 has the high level, the NMOS transistor 54 configuring the three-state inverter 5a-1 is placed in an on state. Accordingly, for example, when the Data signal 11 has the low level, the NMOS transistor 54 and the NMOS transistor 55 are placed in an on state, and consequently, the three-state inverter 5a-1 outputs a low-level signal.

On the other hand, the outputs of the selectors 41-2 to 41-m are inputted to the corresponding NAND circuits 47.

Here, since the block select signals 2 to m have the low level, a low-level signal is inputted to the NAND circuit 47 connected individually to the selectors 41-2 to 41-m.

Accordingly, irrespective of the outputs from the selectors 41-2 to 41-m, the NAND circuits 47 connected individually to the selectors 41-2 to 41-m output a high-level signal to the three-state inverters 5a-2 to 5a-m. In particular, the input signal to the three-state inverter is fixed to the high level by the block select signal. In other words, the output of the NAND circuit 47 is fixed to the high level by the block select signal.

Accordingly, the PMOS transistor 56 provided in the three-state inverters 5a-2 to 5a-m is placed in an off state.

It is to be noted that, since the block select signals 2 to m have the low level, a low-level signal is inputted to the gate of the NMOS transistor 54 provided in the three-state inverters 5a-2 to 5a-m and the NMOS transistor 45 is placed into an off state.

In particular, when the block select signals 2 to (m/2) have the low level, the NMOS transistor 54 and the PMOS transistor 56 included individually in the three-state inverters 5a-2 to 5a-m are placed in an off state. Accordingly, the outputs of the three-state inverters 5a-2 to 5a-m are placed in a high-impedance state. In particular, since the input to the three-state inverter is fixed to the high level using the block select signal, the high-impedance state is implemented by three MOS transistors.

Accordingly, a high-level signal is outputted from the output of the static selector circuit 20. In particular, the static selector circuit 20 outputs Data 11.

In the example of the fourth embodiment, the block select signal is inputted to the NAND circuit 47 as described above to control the output to the three-state inverter 5a. In particular, when the block select signal has the high level, the NAND circuit 47 outputs a value corresponding to the Data signal. However, when the block select signal has the low level, the output of the NAND circuit 47 is fixed to the high level irrespective of the inputted Data signal. Since the input to the three-state inverter 5a is fixed to the high level, the output of the three-state inverter 5a is placed in a high-impedance state.

In this manner, with the fourth embodiment, when the block select signal has the low level, since the input to the three-state inverter 5a to which the block select signal is inputted is fixed, the three-state inverter can be configured from three MOS transistors. Further, since only one PMOS transistor is provided between the output terminal of the three-state inverter 5a and the power supply, the speed of charging the output capacitance of the three-state inverter 5a can be increased. In particular, with the three-state inverter 5a according to the fourth embodiment, the speed of operation when a signal of the high level is outputted can be increased.

Further, with the fourth embodiment, since the three-state inverter 5a is configured from three MOS transistors, low power consumption can be implemented in comparison with the conventional three-state inverter configured from four MOS transistors.

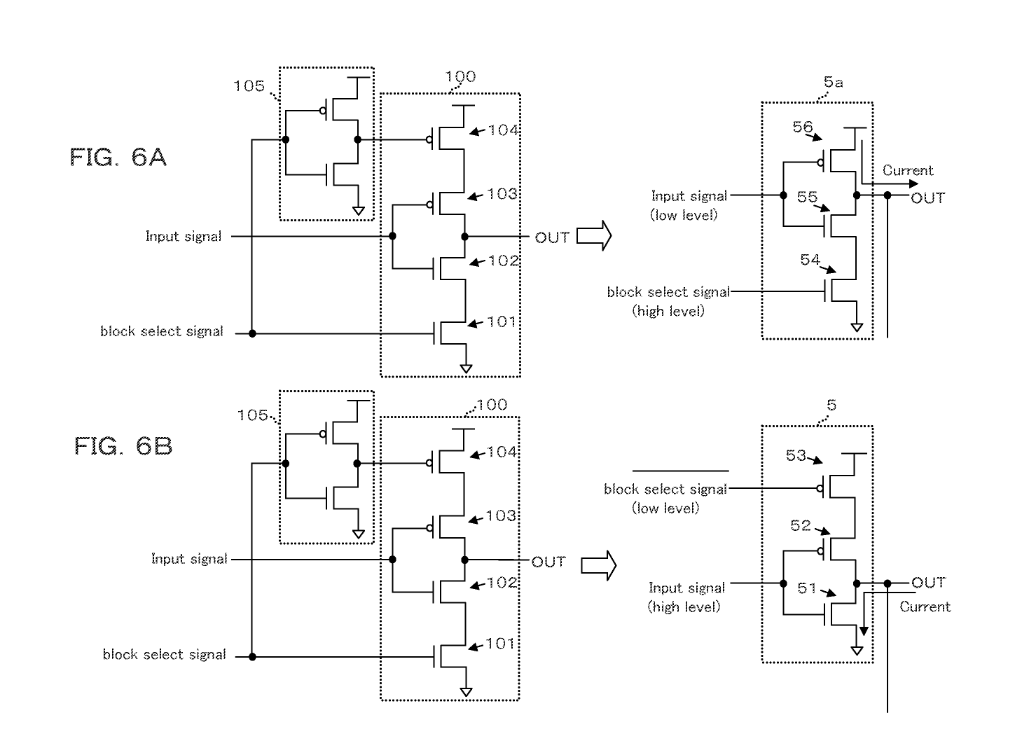

As described in detail above, when the block select signal has the high level and the signal inputted to the three-state inverter 5 has the low level, the speed for outputting the high level can be increased (refer to FIG. 6(A)). On the other hand, when the block select signal has the high level and the signal inputted to the three-state inverter 5 has the high level, the outputting speed of the low level can be increased (refer to FIG. 6(B)).

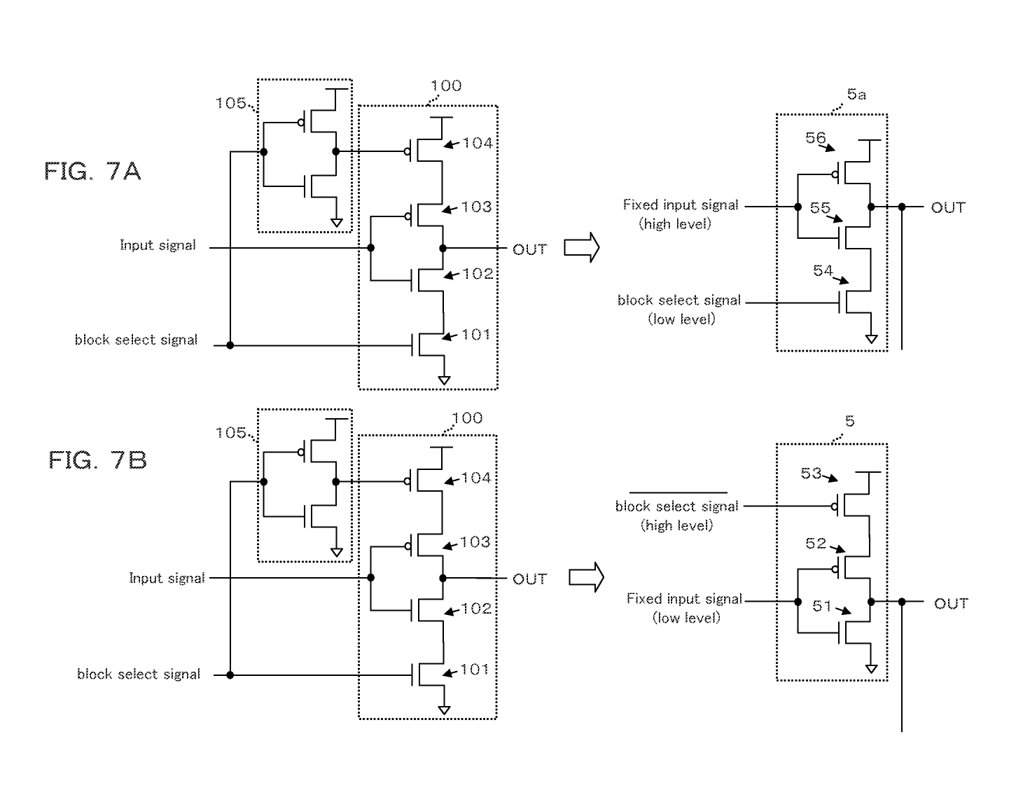

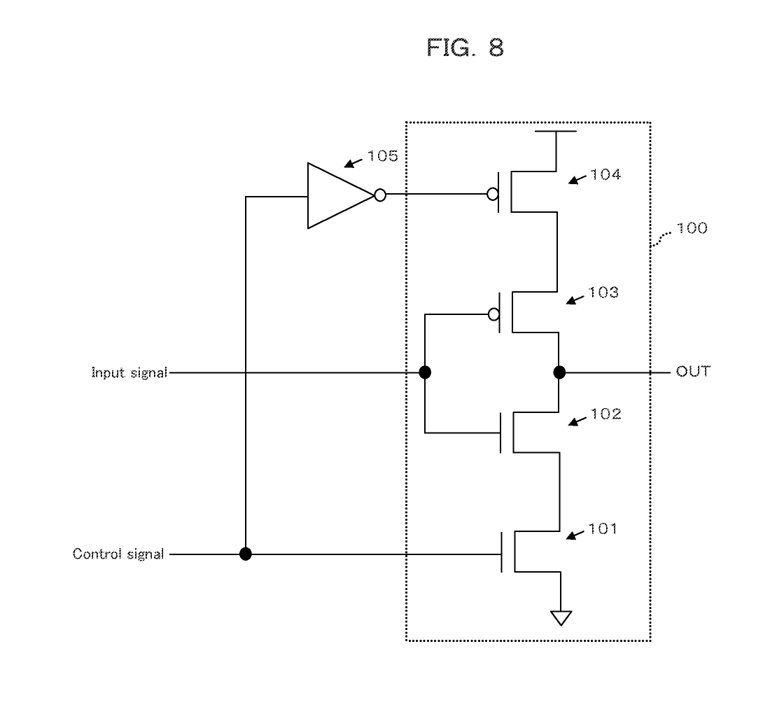

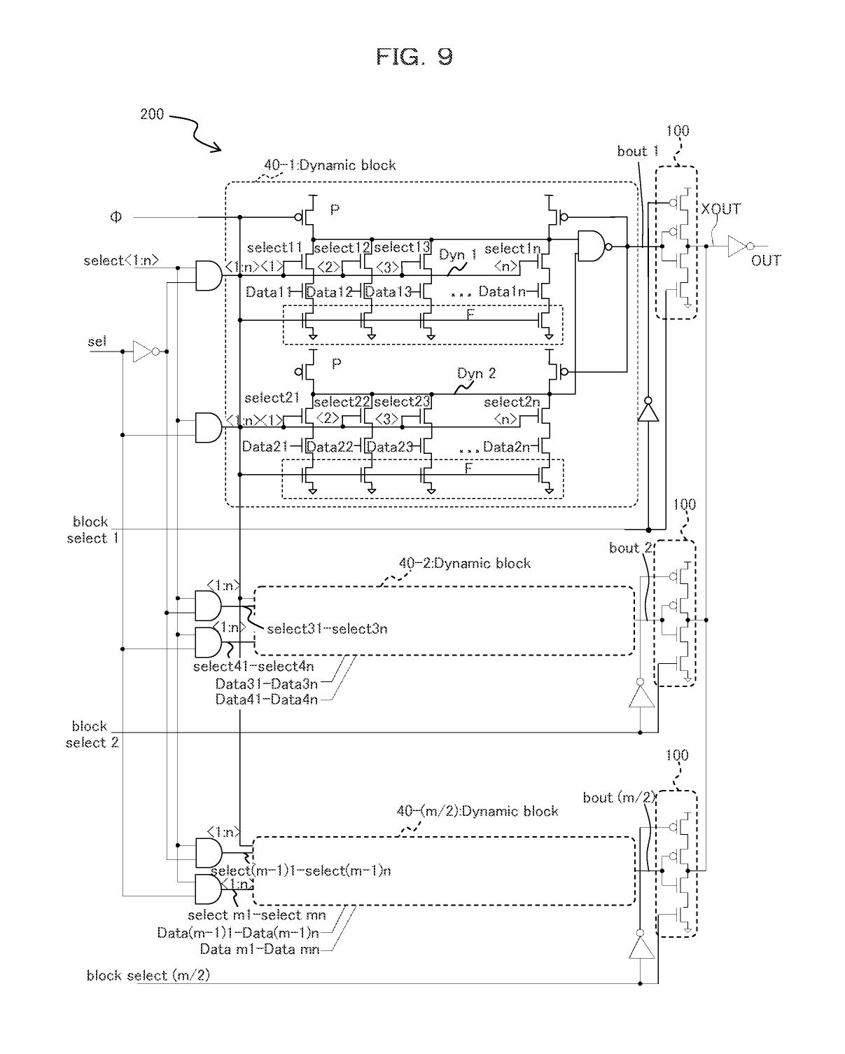

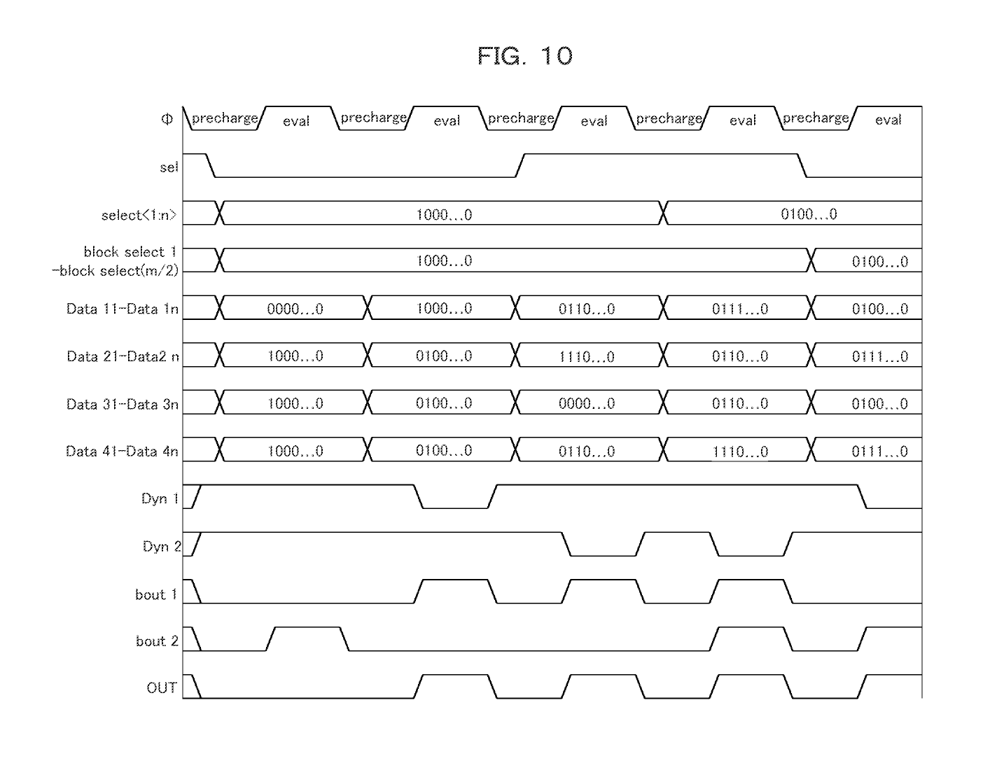

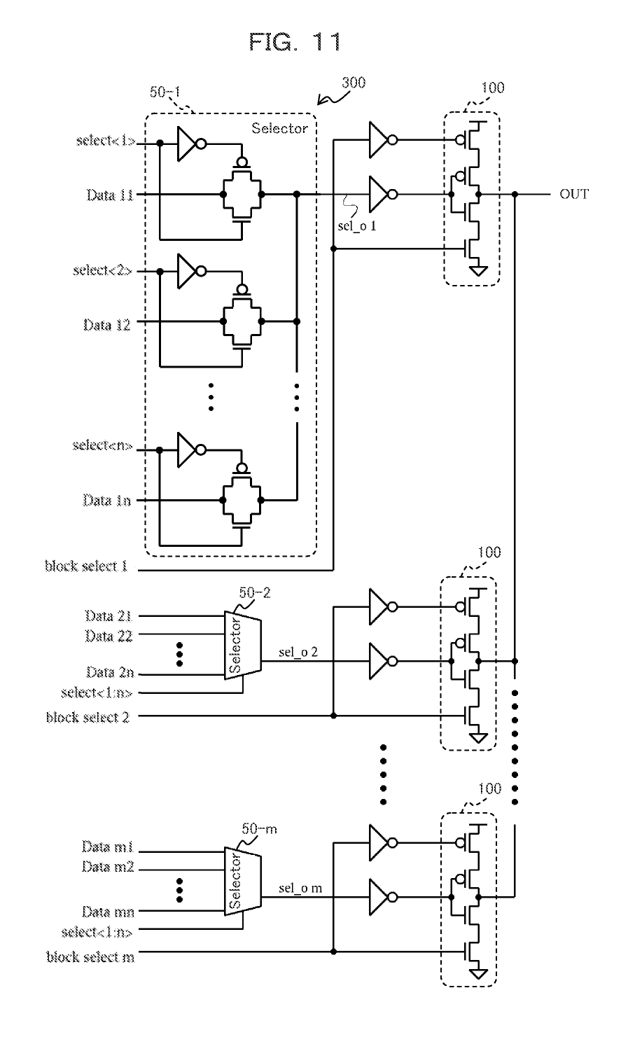

Further, when the block select signal has the low level, the signal inputted to the three-state inverter 5 is fixed to the high level. Consequently, the output of the three-state inverter 5 configured from three MOS transistors with one PMOS transistor removed is placed in a high-impedance state (refer to FIG. 7(A)). On the other hand, when the block select signal has the low level, the signal inputted to the three-state inverter 5a is fixed to the low level. Consequently, the output of the three-state inverter 5a configured from three MOS transistors with one PMOS transistor removed is placed in a high-impedance state (refer to FIG. 7(B)). Accordingly, reduction in power consumption can be anticipated.

### [E] Others

It is to be noted that the disclosed technology is not limited to the embodiments described above but can be modified in various manners without departing from the spirit and the scope of the present invention.

For example, while, in an example of the present embodiment, the source of the NMOS transistors N3, N6, 51 and 54 is grounded, the disclosed technology is not limited to this, but the source described may be connected to a negative power supply (example of the second power supply).

Further, while, in an example of the present embodiment, a case in which the three-state inverter 5 or 5a is used in the select circuit is taken as an example, the disclosed technology is not limited to this, but the three-state inverter 5 or 5a according to the present embodiment may be applied to other circuits.

With the integrated circuit disclosed herein, the operating speed of the integrated circuit can be increased and power consumption of the integrated circuit can be reduced.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. An integrated circuit, comprising:
an outputting unit in which a CMOS inverter configured from a first MOS transistor and a second MOS transistor for outputting a second signal using a first signal as an input thereto and a third MOS transistor that includes a gate terminal to which a control signal for controlling the outputting of the second signal is inputted and that is in an off state when the control signal indicates inhibition of the outputting of the second signal are cascade-connected to each other between a first power supply and a second power supply that supplies a lower voltage than that of the first power supply; and
a fixing unit that fixes a value of the first signal based on the control signal; wherein
when the control signal indicates inhibition of the outputting of the second signal,
the fixing unit fixes the value of the first signal to a value with which the first or second MOS transistor connected to the first or second power supply without the intervention of the third MOS transistor is fixed to an off state.

2. The integrated circuit according to claim 1, wherein the first MOS transistor and the third MOS transistor are PMOS transistors and the second MOS transistor is an NMOS transistor; and
a source terminal of the third MOS transistor is connected to the first power supply and a source terminal of the second MOS transistor is connected to the second power supply.

3. The integrated circuit according to claim 1, wherein the first MOS transistor is a PMOS transistor and the second MOS transistor and the third MOS transistor are NMOS transistors; and
a source terminal of the first MOS transistor is connected to the first power supply and a source terminal of the third MOS transistor is connected to the second power supply.

4. The integrated circuit according to claim 1, wherein the outputting unit is connected to an output of a selection unit that outputs one of a plurality of data signals inputted thereto; and
the fixing unit fixes the value of the first signal by fixing the output of the selection unit.

5. The integrated circuit according to claim 2, wherein the outputting unit is connected to an output of a selection unit that outputs one of a plurality of data signals inputted thereto;
the fixing unit includes an AND circuit that outputs an AND value among a first selection signal for selecting a data signal to be outputted from among the plurality of inputted data signals, a second selection signal for selecting a data signal to be used from among the plurality of inputted data signals and the control signal; and
the selection unit determines an output thereof in response to the output of the AND circuit.

6. The integrated circuit according to claim 3, wherein the outputting unit is connected to an output of a selection unit that outputs one of a plurality of data signals inputted thereto;
the fixing unit includes a NOR circuit that outputs a NOR value among a value obtained by inverting a first selection signal for selecting a data signal to be outputted from among the plurality of inputted data signals, another value obtained by inverting a second selection signal for selecting a data signal to be used from among the plurality of inputted data signals and a further value obtained by inverting the control signal; and
the selection unit determines an output thereof in response to the output of the NOR circuit.

7. The integrated circuit according to claim 2, wherein the fixing unit outputs, as the first signal, a NOR value between an output of a selection unit that outputs one of a plurality of data signals thereto in response to a selection signal and a value obtained by inverting the control signal.

8. The integrated circuit according to claim 3, wherein the fixing unit outputs, as the first signal, a NOR value between an output of a selection unit that outputs one of a plurality of data signals inputted thereto in response to a selection signal and the control signal.
